(19) United States
(12) Patent Application Publication
(10) Pub. No.: US 2026/0321297 A1
(43) Pub. Date: Oct. 15, 2026

(54) SEMICONDUCTOR MEMORY DEVICE AND MANUFACTURING METHOD OF THE SEMICONDUCTOR MEMORY DEVICE

(71) Applicant: SK hynix Inc., Gyeonggi-do (KR)

(72) Inventors: Won Geun CHOI, Gyeonggi-do (KR); Jung Shik JANG, Gyeonggi-do (KR); Rho Gyu KWAK, Gyeonggi-do (KR); Mi Seong PARK, Gyeonggi-do (KR); In Su PARK, Gyeonggi-do (KR); Na Yeong YANG, Gyeonggi-do (KR); Seok Min CHOI, Gyeonggi-do (KR)

(21) Appl. No.: 19/352,592

(22) Filed: Oct. 8, 2025

(30) Foreign Application Priority Data
Apr. 10, 2025 (KR) 10-2025-0046903

(51) Int. Cl. G11C 5/06; G11C 16/04; H10B 43/10; H10B 43/27; H10B 43/35

(52) U.S. Cl. CPC G11C 5/063; G11C 16/0483; H10B 43/10; H10B 43/27; H10B 43/35

(57) ABSTRACT

A semiconductor memory device includes an insulating layer, a gate stack over the insulating layer, and a semiconductor pillar extending in the stacking direction and including a first section extending through the first insulating layer and a second section extending through the gate stack. Each of the first section and the second section of the semiconductor pillar comprises a first channel portion forming a first sidewall, a second channel portion forming a second sidewall and spaced apart from the first channel portion, and the first section of the semiconductor pillar further comprise a connecting portion coupling the first channel portion and the second channel portion in the first section of the semiconductor pillar.

### CROSS-REFERENCE TO RELATED APPLICATION

The present application claims priority under 35 U.S.C. § 119(a) to Korean patent application number 10-2025-0046903 filed on Apr. 10, 2025, in the Korean Intellectual Property Office, the entire disclosure of which is incorporated herein by reference.

### BACKGROUND

### 1. Technical Field

An embodiment of the present disclosure may relate to a semiconductor memory device, and more particularly, to a semiconductor memory device including a three-dimensional memory cell array and a method of manufacturing the semiconductor memory device.

### 2. Related Art

Semiconductor memory devices are applicable to electronic systems in various fields, such as automobiles, medical devices, and data centers as well as small electronic devices. As a result, the demand for semiconductor memory devices is increasing.

A semiconductor memory device includes a memory cell array, and the memory cell array includes a plurality of memory cells for storing data. The semiconductor memory device may be a two-dimensional semiconductor memory device including a two-dimensional memory cell array or a three-dimensional semiconductor memory device including a three-dimensional memory cell array.

A plurality of memory cells of a three-dimensional memory cell array are arranged in an X-axis direction, a Y-axis direction, and a Z-axis direction. In a two-dimensional memory cell array, a plurality of memory cells are arranged in the X-axis direction and the Y-axis direction. Due to this structural difference, a three-dimensional memory cell array is advantageous for large-scale mass production of a semiconductor memory device compared to the two-dimensional memory cell array.

A three-dimensional memory cell array may include a semiconductor pillar and a plurality of conductive layers stacked along the semiconductor pillar. To improve the integration of the three-dimensional memory cell array, the semiconductor pillar may be divided into channel portions. However, dividing the semiconductor pillar into channel portions may increase process complexity and process defects of the semiconductor memory device.

### SUMMARY

According to an embodiment of the present disclosure, a semiconductor memory device may include: a first insulating layer including a first surface extending parallel to an XY plane; a gate stack arranged over the first surface of the first insulating layer and including a plurality of conductive layers and a plurality of second insulating layers, the plurality of conductive layers and the plurality of second insulating layers arranged alternately in a stacking direction crossing the XY plane; a semiconductor pillar extending in the stacking direction and including a first section extending through the first insulating layer and a second section extending through the gate stack, the semiconductor pillar having a major axis and a minor axis in the XY plane and including a first sidewall and a second sidewall defined on opposite sides of the minor axis; a first memory pattern between the first sidewall of the semiconductor pillar and the gate stack; and a second memory pattern between the second sidewall of the semiconductor pillar and the gate stack. Each of the first section and the second section of the semiconductor pillar may comprise a first channel portion forming the first sidewall, a second channel portion forming the second sidewall and spaced apart from the first channel portion and the first section of the semiconductor pillar may further comprise a connecting portion coupling the first channel portion and the second channel portion in the first section of the semiconductor pillar.

According to an embodiment of the present disclosure, a method of manufacturing a semiconductor memory device may include: forming a lower insulating layer extending parallel to an XY plane; alternately stacking a plurality of first material layers and a plurality of second material layers over the lower insulating layer in a stacking direction crossing the XY plane; forming a hole including a first section passing through the lower insulating layer and a second section extending from the first section through the plurality of first material layers and the plurality of second material layers, the hole having a major axis and a minor axis in the XY plane; forming a memory layer on a sidewall of the lower insulating layer adjacent to the hole and extending into the second section of the hole; forming a recess by etching a portion of the memory layer overlapping with the minor axis of the hole; forming a channel layer on an inner wall of the memory layer, the channel layer including a protrusion protruding to the recess; removing the plurality of first material layers to form a plurality of openings; replacing the protrusion of the channel layer with a channel separation structure through the plurality of openings; and forming a plurality of conductive layers in the plurality of openings, respectively.

### BRIEF DESCRIPTION OF THE DRAWINGS

FIG. 1 is a circuit diagram illustrating a memory cell array of a semiconductor memory device according to an embodiment of the present disclosure;

FIGS. 2A and 2B are diagrams illustrating a semiconductor memory device according to embodiments of the present disclosure;

FIG. 3 is a perspective view of a semiconductor pillar as shown in FIGS. 2A and 2B;

FIGS. 4A, 4B, 4C, and 4D are plan views illustrating a cross-section of a cell pillar structure as shown in FIGS. 2A and 2B;

FIG. 5 is an exploded perspective view illustrating a semiconductor memory device as shown in FIGS. 2A and 2B;

FIG. 6A is a cross-sectional view showing various configurations of a semiconductor memory device according to an embodiment of the present disclosure, taken along a major axis of a hole as shown in FIGS. 4A to 4C, and FIG. 6B is a cross-sectional view showing various configurations of a semiconductor memory device, taken along a minor axis of a hole as shown in FIGS. 4A to 4C;

FIG. 7A is a cross-sectional view showing various configurations of a semiconductor memory device according to an embodiment of the present disclosure, taken along a major axis of a hole as shown in FIGS. 4A to 4C, and FIG. 7B is a cross-sectional view showing various configurations of a semiconductor memory device taken along a minor axis of a hole as shown in FIGS. 4A to 4C;

FIGS. 8A and 8B are plan views showing a cross-section of a cell pillar structure according to embodiments of the present disclosure;

FIGS. 9A, 9B, and 9C are diagrams illustrating a preliminary stack and a hole according to embodiments of the present disclosure;

FIGS. 10A, 10B, 11A, 11B, 12A, 12B, 13A, 13B, 13C, 14A, 14B, and 14C are diagrams illustrating various configurations formed in a hole by using a method of manufacturing a semiconductor memory device according to embodiments of the present disclosure;

FIGS. 15A, 15B, 15C, 15D, and 15E are diagrams illustrating a channel separation structure and a connecting portion and a dummy portion of a channel layer formed using a method of manufacturing a semiconductor memory device according to an embodiment of the present disclosure;

FIG. 16 is a cross-sectional view illustrating a plurality of conductive layers formed using a method of manufacturing a semiconductor memory device according to an embodiment of the present disclosure;

FIGS. 17A, 17B, 17C, and 17D are diagrams illustrating various configurations formed using a method of manufacturing a semiconductor memory device according to embodiments of the present disclosure;

FIGS. 18A, 18B, 18C, and 18D are plan views illustrating various configurations formed using a method of manufacturing a semiconductor memory device according to embodiments of the present disclosure; and

FIG. 19 is a block diagram illustrating an electronic system according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Terms, such as “first,” “second,” etc., are used to distinguish between various elements and do not imply size, order, priority, quantity, or importance of the elements. For example, a first element may be named as a second element in one example, and the second element may be named as a first element in another example. Terms, such as “top,” “over,” “on,” “side,” “upper,” “lower,” “row,” “column,” “inner,” “outer” and other terms implying relative spatial relationship or orientation, are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer etc., is referred to as being “on,” “connected to,” or “coupled to” another element or layer etc., it can be directly on, connected, or coupled to the other element or layer etc., or intervening elements or layers etc., may be present. In contrast, when an element or layer etc., is referred to as being “directly on,” “directly connected to,” or “directly coupled to” another element or layer etc., there are no intervening elements or layers etc., present.

Various embodiments of the present disclosure are directed to a semiconductor memory device and a method of manufacturing the semiconductor memory device, which can reduce process complexity and process defects.

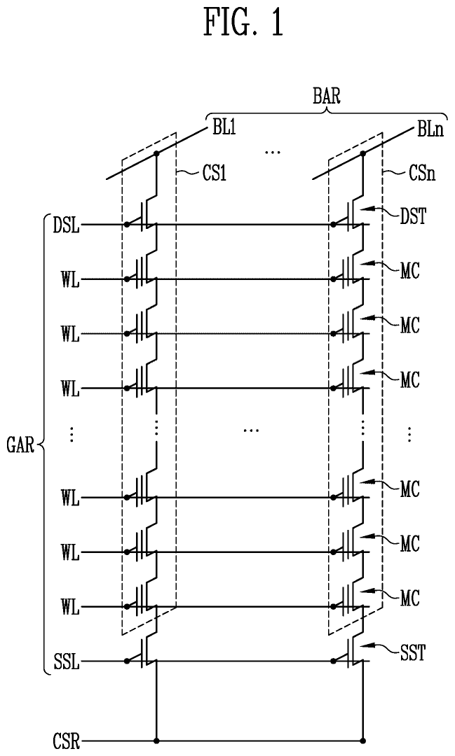

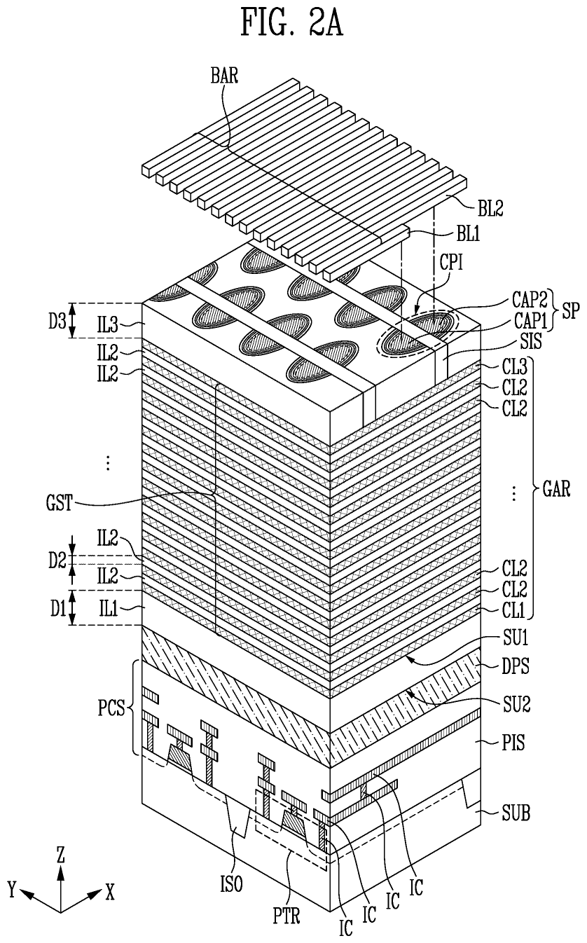

FIG. 1 is a circuit diagram illustrating a memory cell array of a semiconductor memory device according to an embodiment of the present disclosure.

Referring to FIG. 1, the memory cell array of the semiconductor memory device includes a plurality of memory cell strings CS1 to CSn, where n is a natural number equal to or greater than 2. The plurality of memory cell strings CS1 to CSn are coupled to a gate array GAR, a bit line array BAR, and a common source layer CSR.

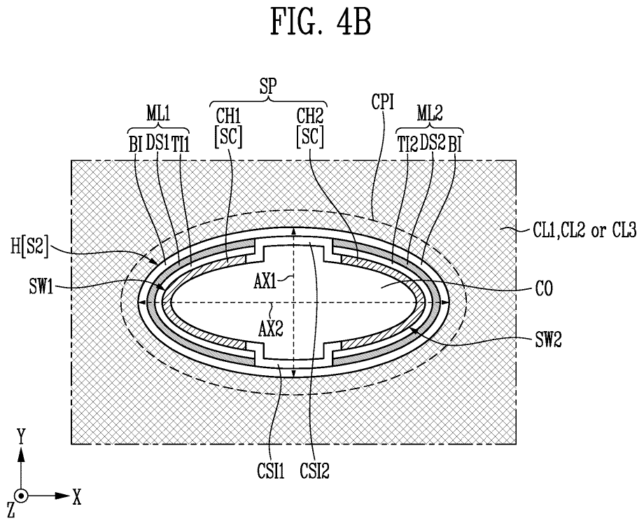

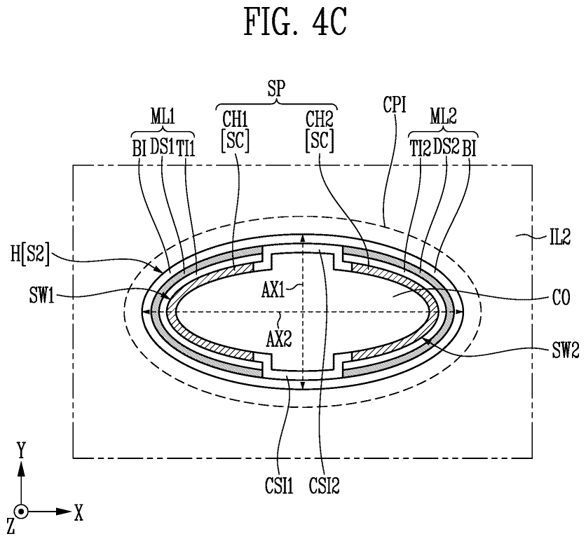

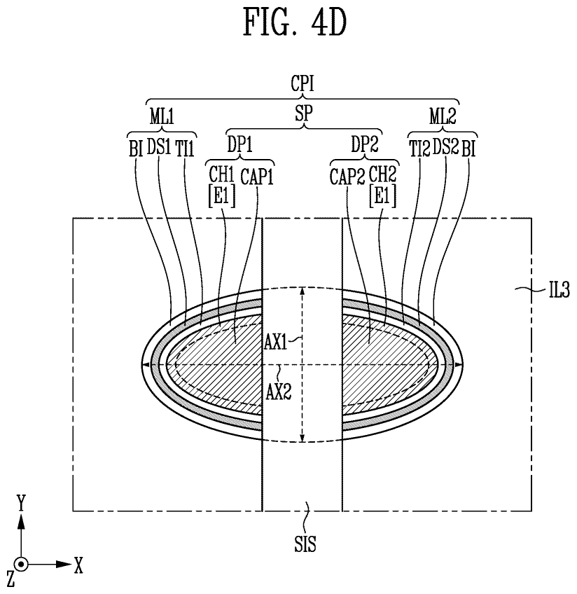

Each of the plurality of memory cell strings CS1 to CSn includes at least one source select transistor SST, a plurality of memory cells MC, and at least one drain select transistor DST. The plurality of memory cells MC are stacked between the source select transistor SST and the drain select transistor DST. The source select transistor SST, the plurality of memory cells MC, and the drain select transistor DST are coupled in series via a corresponding channel portion (e.g., CH1 or CH2 in FIG. 4).

The gate array GAR includes a source select line SSL, a plurality of word lines WL, and a drain select line DSL. The source select line SSL may serve as a gate electrode of the source select transistor SST, each of the word lines WL may serve as a gate electrode of a corresponding one of the memory cells MC, and the drain select line DSL may serve as a gate electrode of the drain select transistor DST.

The bit line array BAR includes a plurality of bit lines BL1 to BLn, where n is a natural number equal to or greater than 2. Each of the plurality of bit lines BL1 to BLn is coupled to a corresponding one of the plurality of memory cell strings CS1 to CSn. Each of the plurality of bit lines BL1 to BLn is coupled to a channel portion of the corresponding memory cell string to selectively control the channel portion of the corresponding memory cell string. A voltage may be applied to precharge the corresponding channel portion to each of the plurality of bit lines BL1 to BLn.

The plurality of memory cell strings CS1 to CSn are coupled in parallel to the common source layer CSR. A voltage may be applied to the common source layer CSR to discharge the plurality of channel portions of the plurality of memory cell strings CS1 to CSn.

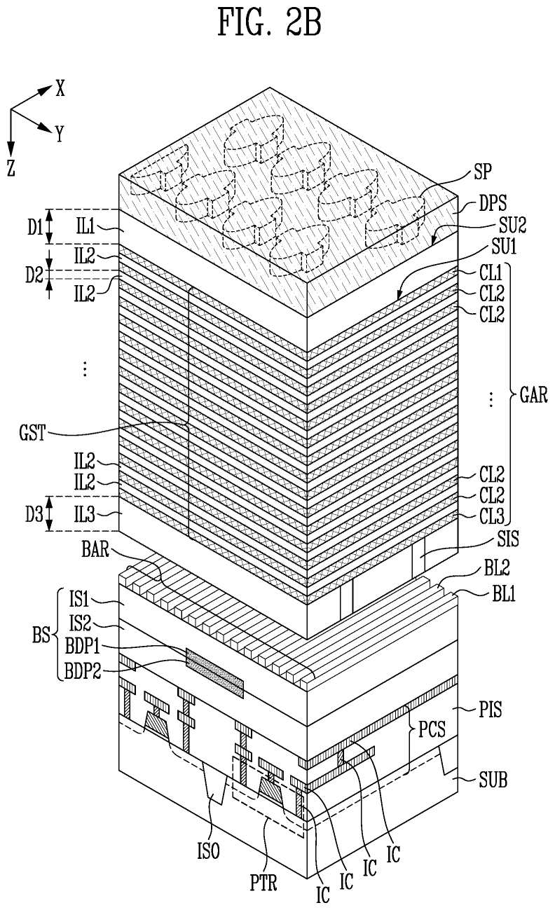

FIGS. 2A and 2B are diagrams illustrating a semiconductor memory device according to embodiments of the present disclosure.

Referring to FIGS. 2A and 2B, the semiconductor memory device includes the gate array GAR, the bit line array BAR, a plurality of cell pillar structures CPI, a doped semiconductor structure DPS, and a peripheral circuit structure PCS. The gate array GAR, the bit line array BAR, and the doped semiconductor structure DPS are arranged over the peripheral circuit structure PCS. The gate array GAR is between the bit line array BAR and the doped semiconductor structure DPS. The plurality of cell pillar structures CPI may extend through the gate array GAR.

The gate array GAR includes a plurality of conductive layers CL1, CL2, and CL3 of a gate stack GST. Each of the plurality of conductive layers CL1, CL2, and CL3 may extend parallel to the XY plane. The plurality of conductive layers CL1, CL2, and CL3 may be spaced apart from each other in a stacking direction (e.g., a Z-axis direction) which intersects the XY plane. Each of the plurality of conductive layers CL1, CL2, and CL3 may include various conductive materials, such as a doped semiconductor layer, a metal layer, and the like. The doped semiconductor layer may include a doped silicon layer. The metal layer may include tungsten, copper, molybdenum, and the like. Each of the plurality of conductive layers CL1, CL2, and CL3 may further include a metal nitride layer. The metal nitride layer may include titanium nitride, tantalum nitride, or the like.

The plurality of conductive layers CL1, CL2, and CL3 may include at least one first conductive layer CL1, a plurality of second conductive layers CL2, and at least one third conductive layer CL3. The plurality of second conductive layers CL2 are spaced apart from each other in the stacking direction between the first conductive layer CL1 and the third conductive layer CL3. The first conductive layer CL1 is closer to the doped semiconductor structure DPS than the plurality of second conductive layers CL2, and the third conductive layer CL3 is closer to the bit line array BAR than the plurality of second conductive layers CL2. The first conductive layer CL1 may serve as the source select line SSL, as shown in FIG. 1, the plurality of second conductive layers CL2 may serve as the plurality of word lines WL, as shown in FIG. 1, and the third conductive layer CL3 may serve as the drain select line DSL, as shown in FIG. 1.

The gate stack GST may be disposed over a first surface SU1 of a first insulating layer IL1. The first surface SU1 of the first insulating layer IL1 may extend parallel to the XY plane. The gate stack GST may include a plurality of second insulating layers IL2 arranged alternately with the plurality of conductive layers CL1, CL2, and CL3 in the stacking direction. A third insulating layer IL3 may be disposed over a surface of the gate stack GST opposite the first insulating layer IL1. The first insulating layer IL1 is adjacent to the first conductive layer CL1 of the gate stack GST, and the third insulating layer IL3 is adjacent to the third conductive layer CL3 of the gate stack GST. The plurality of second insulating layers IL2 are spaced apart from each other in the stacking direction between the first insulating layer IL1 and the second insulating layer IL2. Each of the first insulating layer IL1, the plurality of second insulating layers IL2, and the third insulating layer IL3 may include an insulating material layer, such as a silicon oxide layer, a silicon oxynitride layer, or the like. In the stacking direction, each of a thickness D1 of the first insulating layer IL1 and a thickness D3 of the third insulating layer IL3 may be greater than a thickness D2 of each of the plurality of second insulating layers IL2.

The plurality of cell pillar structures CPI extend in the stacking direction through the first insulating layer IL1, the plurality of second insulating layers IL2, and the third insulating layer IL3. Each of the first conductive layer CL1, the plurality of second conductive layers CL2, and the third conductive layer CL3 may be formed in an all-around structure which surrounds a sidewall of each of the cell pillar structures CPI in an XY plane.

Each cell pillar structure CPI may include a semiconductor pillar SP, and the semiconductor pillar SP may be divided to form two or more memory cell strings. In an embodiment, the semiconductor pillar SP of the cell pillar structure CPI may include two or more channel portions and two or more capping portions. The two or more capping portions of the semiconductor pillar SP may be arranged in the third insulating layer IL3 and may be separated from each other by an isolation insulating structure SIS. In an embodiment, the semiconductor pillar SP may include a first capping portion CAP1 and a second capping portion CAP2 divided by the isolation insulating structure SIS. The isolation insulating structure SIS may extend between the first capping portion CAP1 and the second capping portion CAP2 into the third insulating layer IL3.

The plurality of bit lines (e.g., BL1 and BL2) of the bit line array BAR may extend next to each other in the XY plane. In an embodiment, the plurality of bit lines (e.g., BL1 and BL2) may extend in an X-axis direction and may be spaced apart in a Y-axis direction.

Two or more capping portions are electrically coupled to different bit lines of the bit line array BAR. In an embodiment, the first capping portion CAP1 may be electrically coupled to a first bit line BL1, and the second capping portion CAP2 may be electrically coupled to a second bit line BL2.

The bit line array BAR may be spaced apart from the gate stack GST by the third insulating layer IL3. Though not shown in FIGS. 2A and 2B, a fourth insulating layer may be disposed between the bit line array BAR and the third insulating layer IL3, and the fourth insulating layer may be penetrated by a plurality of conductive bit line connection structures. Each of the conductive bit line connection structures may be designed in various configurations to couple a corresponding bit line (e.g., BL1) to a capping portion (e.g., CAP1) of a corresponding semiconductor pillar SP.

The doped semiconductor structure DPS is disposed under, in the Z direction, a second surface SU2 of the first insulating layer IL1. The second surface SU2 opposes the first surface SU1. The doped semiconductor structure DPS is spaced from the first conductive layer CL1 of the gate stack GST by the first insulating layer IL1. The doped semiconductor structure DPS includes at least one doped semiconductor layer extending along the XY plane. The doped semiconductor layer of the doped semiconductor structure DPS may include n-type impurities or p-type impurities. In an embodiment, the doped semiconductor structure DPS may include one or both of a first conductivity-type doped semiconductor layer including n-type impurities as majority carriers and a second conductivity-type doped semiconductor layer including p-type impurities as majority carriers. The first conductivity-type doped semiconductor layer may be provided as the common source layer CSR as described with reference to FIG. 1, and the second conductivity type doped semiconductor layer may be provided as a well region.

One of the doped semiconductor structure DPS and the bit line array BAR may be closer to the peripheral circuit structure PCS than the other. In an embodiment, the doped semiconductor structure DPS may be closer to the peripheral circuit structure PCS than the bit line array BAR, as shown in FIG. 2A. In an embodiment, the bit line array BAR may be closer to the peripheral circuit structure PCS than the doped semiconductor structure DPS, as shown in FIG. 2B. The doped semiconductor structure DPS may form a contact surface with the semiconductor pillar SP of the cell pillar structure CPI. The contact surface may be formed on a portion of a sidewall of the semiconductor pillar SP, an end portion of the semiconductor pillar SP, and the like.

The peripheral circuit structure PCS may include an input/output circuit, a control circuit, a voltage generation circuit, a row decoder, a column decoder, a page buffer, and the like, and may include a plurality of transistors PTR constituting at least some of these components, and a plurality of interconnections IC coupled to the plurality of transistors PTR.

Each of the plurality of transistors PTR is disposed on an active region of a semiconductor substrate SUB divided by an isolation layer ISO. The semiconductor substrate SUB includes a semiconductor material. In an embodiment, the semiconductor material may include one or two or more of a group IV semiconductor, a group III-V compound semiconductor, and a group II-VI compound semiconductor. The group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The semiconductor substrate SUB may further include a dielectric layer. In an embodiment, the semiconductor substrate SUB may be a silicon-on-insulator (SOI) substrate, a germanium-on-insulator (GeOI) substrate, or the like. The semiconductor substrate SUB may further include an organic material. In an embodiment, the semiconductor substrate SUB may include graphene.

The semiconductor substrate SUB may be a bulk wafer or an epitaxial layer grown by selective epitaxial growth (SEG). Alternatively, the semiconductor substrate SUB may be a layer formed by metal induced lateral crystallization (MILC) and may partially include metal.

The semiconductor substrate SUB may have a single crystal, polycrystalline, or amorphous state. The semiconductor substrate SUB may include group II, group III, group IV, group V, or group VI impurities. In an embodiment, the semiconductor substrate SUB may include an n-well region doped with n-type impurities, a p-well region doped with p-type impurities, or both an n-well region and a p-well region.

The transistor PTR is covered by a peripheral insulating structure PIS over the semiconductor substrate SUB. The plurality of interconnections IC may be formed in the peripheral insulating structure PIS, and may include a plurality of conductive lines and a plurality of conductive contacts for electrical connection.

Referring to FIG. 2A, the doped semiconductor structure DPS may be disposed over the peripheral insulating structure PIS.

Referring to FIG. 2B, the semiconductor memory device may further include a bonding structure BS. The bonding structure BS may be disposed between the bit line array BAR and the peripheral circuit structure PCS. The bonding structure BS may include a first interposed insulating structure IS1, a second interposed insulating structure IS2, a first conductive bonding pattern BDP1, and a second conductive bonding pattern BDP2. The first interposed insulating structure IS1 is placed between the bit line array BAR and the peripheral insulating structure PIS, and the second interposed insulating structure IS2 is placed between the first interposed insulating structure IS1 and the peripheral insulating structure PIS. The first interposed insulating structure IS1 is bonded to the second interposed insulating structure IS2. The first conductive bonding pattern BDP1 is disposed in the first interposed insulating structure IS1, and the second conductive bonding pattern BDP2 is disposed in the second interposed insulating structure IS2. The first conductive bonding pattern BDP1 is bonded to the second conductive bonding pattern BDP2 and is electrically coupled to the second conductive bonding pattern BDP2.

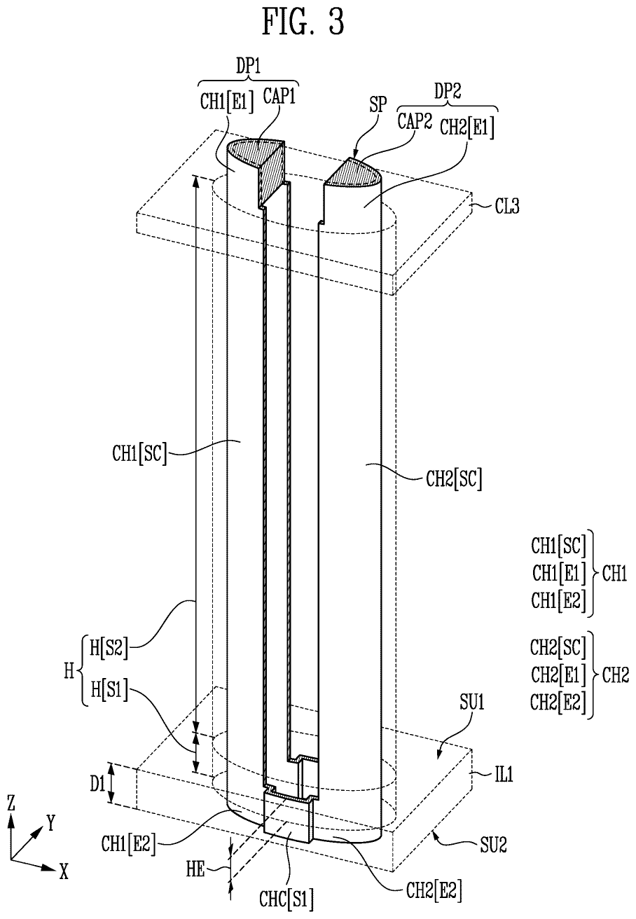

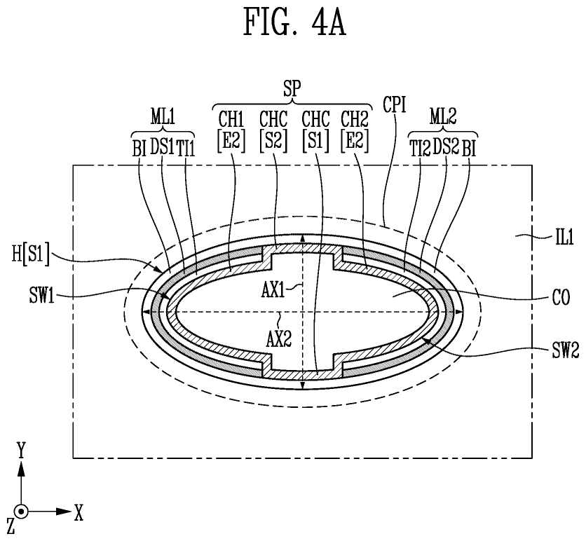

The semiconductor pillar SP may be formed as an integral structure, rather than being divided into two or more parts in the doped semiconductor structure DPS. The semiconductor pillar SP is described below in detail with reference to FIGS. 3, 4A, 4B, 4C, and 4D.

FIG. 3 is a perspective view of the semiconductor pillar SP as shown in FIGS. 2A and 2B.

Referring to FIGS. 2A, 2B, and 3, the semiconductor pillar SP is disposed in a hole H. The hole H extends in the stacking direction (e.g., the Z-axis direction) through the first insulating layer IL1 and the gate stack GST. The hole H includes a first section H[S1] extending through the first insulating layer IL1 and a second section H[S2] extending through the gate stack GST. By extension, because the semiconductor pillar SP is disposed in the hole H, the semiconductor pillar SP includes a first section extending through the first insulating layer IL1 and a second section extending through the gate stack GST. The first section H[S1] extends from the second surface SU2 to the first surface SU1 through the first insulating layer IL1. The second section H[S2] extends through the third conductive layer CL3 of the gate stack GST and is coupled to the first section H[S1]. The first section of the semiconductor pillar SP is disposed in the first section H[S1] of the hole H and the second section of the semiconductor pillar SP is disposed to the second section H[S2] of the hole H. The semiconductor pillar SP extends into the doped semiconductor structure DPS and the third insulating layer IL3.

The semiconductor pillar SP includes the first capping portion CAP1, the second capping portion CAP2, a first channel portion CH1, a second channel portion CH2, and a connecting portion. The connecting portion as shown in FIG. 3 is a first side pattern CHC[S1] which is part of the connecting portion. Each of the first capping portion CAP1, the second capping portion CAP2, the first channel portion CH1, the second channel portion CH2, and the connecting portion (e.g., CHC[S1]) includes a semiconductor material, such as silicon (Si), germanium (Ge), or a mixture thereof.

Each of the first section and the second section of the semiconductor pillar SP comprises the first channel portion CH1 and the second channel portion CH2 and the first second of the semiconductor pillar SP further comprises the connecting portion (e.g., CHC[S1]). Each of the first channel portion CH1 and the second channel portion CH2 includes a string channel region CH1[SC] or CH2[SC], a first end portion CH1[E1] or CH2[E1], and a second end portion CH1[E2] or CH2[E2]. Each of the string channel region CH1[SC] of the first channel portion CH1 and the string channel region CH2[SC] of the second channel portion CH2 is disposed in the second section H[S2] of the hole H. Each of the string channel region CH1[SC] of the first channel portion CH1 and the string channel region CH2[SC] of the second channel portion CH2 may serve as a channel region of a corresponding memory cell string. Each of the first end portion CH1[E1] of the first channel portion CH1 and the second end portion CH2[E1] of the second channel portion CH2 extends from the corresponding string channel region CH1[SC] or CH2[SC] and may extend through the third insulating layer IL3 as shown in FIGS. 2A and 2B. Each of the second end portion CH1[E2] of the first channel portion CH1 and the second end portion CH2[E2] of the second channel portion CH2 extends from the corresponding string channel region CH1[SC] or CH2[SC] in a direction opposite to the first end portion CH1[E1] or CH2[E1]. The second end portion CH1[E2] of the first channel portion CH1 and the second end portion CH2[E2] of the second channel portion CH2 may extend into the doped semiconductor structure DPS as shown in FIGS. 2A and 2B. The second end portion CH1[E2] of the first channel portion CH1 and the string channel region CH1[SC] may be coupled each other in the first insulating layer IL1. The second end portion CH2[E2] of the second channel portion CH2 and the string channel region CH2[SC] may be coupled each other in the first insulating layer IL1.

The first capping portion CAP1 and the second capping portion CAP2 extend through the third insulating layer IL3. The first capping portion CAP1 and the second capping portion CAP2 are arranged between the first end portion CH1[E1] of the first channel portion CH1 and the second end portion CH2[E1] of the second channel portion CH2. The first capping portion CAP1 is coupled to the first end portion CH1[E1] of the first channel portion CH1, and the second capping portion CAP2 is coupled to the first end portion CH2[E1] of the second channel portion CH2.

The connecting portion (e.g., CHC[S1]) couples the second end portion CH1[E2] of the first channel portion CH1 and the second end portion CH2[E2] of the second channel portion CH2 in the first section H[S1] of the hole H. The connecting portion (e.g., CHC[S1]) may extend into the doped semiconductor structure DPS, and may couple the second end portion CH1[E2] of the first channel portion CH1 and the second end portion CH2[E2] of the second channel portion CH2 in the doped semiconductor structure DPS.

Each of the first capping portion CAP1, the second capping portion CAP2, the first end portion CH1[E1] and the second end portion CH1[E2] of the first channel portion CH1, the first end portion CH2[E1] and the second end portion CH2[E2] of the second channel portion CH2, and the connecting portion (e.g., CHC[S1]) may include n-type impurities, or both n-type impurities and p-type impurities. In an embodiment, each of the first capping portion CAP1, the second capping portion CAP2, the first end portion CH1[E1] and the second end portion CH1[E2] of the first channel portion CH1, the first end portion CH2[E1] and the second end portion CH2[E2] of the second channel portion CH2, and the connecting portion (e.g., CHC[S1]) may include n-type impurities as majority carriers, may be provided as a junction of a memory cell string.

FIGS. 4A, 4B, 4C, and 4D are plan views illustrating the cross-section of the cell pillar structure CPI as shown in FIGS. 2A and 2B. FIG. 4A is a plan view illustrating the cross-section of the cell pillar structure CPI at a first level on which the first insulating layer IL1 as shown in FIGS. 2A and 2B is disposed. The first level is closer to the second surface SU2 than the first surface SU1 as shown in FIGS. 2A and 2B. FIG. 4B is a plan view illustrating the cross-section of the cell pillar structure CPI at a second level where the first conductive layer CL1, each second conductive layer CL2, or the third conductive layer CL3 as shown in FIGS. 2A and 2B is disposed. FIG. 4C is a plan view illustrating the cross-section of the cell pillar structure CPI at a third level where each second insulating layer IL2 as shown in FIGS. 2A and 2B is disposed. FIG. 4D is a plan view illustrating the cross-section of the cell pillar structure CPI at a fourth level where the third insulating layer IL3 as shown in FIGS. 2A and 2B is disposed.

Referring to FIGS. 3, 4A, 4B, and 4C, the hole H has a structure including a minor axis AX1 and a major axis AX2 which intersect each other in the XY plane. In an embodiment, each of the first section H[S1] and the second section H[S2] of the hole H may have an elliptical shape in the XY plane. One of the direction of the minor axis AX1 of the elliptical shape and the direction of the major axis AX2 of the elliptical shape may be the X-axis direction which is a direction of extension of the plurality of bit lines (e.g., BL1 and BL2) as shown in FIGS. 2A and 2B. In an embodiment, the direction of the major axis AX2 may be the X-axis direction. Embodiments of the present disclosure are not limited thereto. In another embodiment, the direction of the major axis AX2 may be the Y-axis direction, or a diagonal direction between the X-axis or Y-axis in the XY plane.

The first channel portion CH1 and the second channel portion CH2 of the semiconductor pillar SP are defined based on the minor axis AX1 and spaced apart from each other. In an embodiment, the first channel portion CH1 and the second channel portion CH2 may be symmetrical with respect to the minor axis AX1. The first channel portion CH1 forms a first sidewall SW1 of the semiconductor pillar SP, and the second channel portion CH2 forms a second sidewall SW2 of the semiconductor pillar SP. The first sidewall SW1 and the second sidewall SW2 may be defined on opposite sides of the minor axis AX1. Each of the first channel portion CH1 and the second channel portion CH2 may form a convex open curve toward the outside of the hole H in the XY plane. The open curve formed by each of the first channel portion CH1 and the second channel portion CH2 may have a vertex intersecting the major axis AX2.

The connecting portion of the semiconductor pillar SP includes the first side pattern CHC[S1] and a second side pattern CHC[S2]. The first side pattern CHC[S1] and the second side pattern CHC[S2] are spaced apart from each other in the direction of the minor axis AX1. The first side pattern CHC[S1] and the second side pattern CHS[S2] may be defined based on the major axis AX2. In an embodiment, the first side pattern CHC[S1] and the second side pattern CHS[S2] may be symmetrical with respect to the major axis AX2. The first side pattern CHC[S1] and the second side pattern CHS[S2] extend in the XY plane from the second end portion CH1[E2] of the first channel portion CH1 toward the second end portion CH2[E2] of the second channel portion CH2, and may couple the first channel portion CH1 and the second channel portion CH2 in the first section H[S1] of the hole H. The first side pattern CHC[S1] and the second side pattern CHC[S2] may extend through the second surface SU2 of the first insulating layer IL1. A portion of each of the first side pattern CHC[S1] and the second side pattern CHC[S2] located in the first insulating layer IL1 has a height HE less than the thickness D1 of the first insulating layer IL1 in the Z-axis direction and is spaced apart from the first surface SU1 of the first insulating layer IL1. The first side pattern CHC[S1] and the second side pattern CHC[S2] may protrude in the direction of the minor axis AX1 toward the outside of the hole H relative to the first channel portion CH1 and the second channel portion CH2.

Referring to FIGS. 3 and 4D, the first capping portion CAP1 and the second capping portion CAP2 of the semiconductor pillar SP are arranged spaced apart from each other in the direction of the major axis AX2 of the hole H. Each of the first capping portion CAP1 and the second capping portion CAP2 includes a convex curved surface in the direction of the major axis AX2. The curved surface of the first capping portion CAP1 is coupled to the first end portion CH1[E1] of the first channel portion CH1, and the curved surface of the second capping portion CAP2 is coupled to the first end portion CH2[E1] of the second channel portion CH2. The first capping portion CAP1 may be integral with the first end portion CH1[E1] of the first channel portion CH1, and the second capping portion CAP2 may be integral with the first end portion CH2[E1] of the second channel portion CH2. The first capping portion CAP1 and the first end portion CH1[E1] of the first channel portion CH1 may form a first doped semiconductor pattern DP1, and the second capping portion CAP2 and the first end portion CH2[E1] of the second channel portion CH2 may form a second doped semiconductor pattern DP2. In an embodiment, each of the first doped semiconductor pattern DP1 and the second doped semiconductor pattern DP2 may have a semi-elliptical shape in the XY plane.

The isolation insulating structure SIS is between the first capping portion CAP1 and the second capping portion CAP2. The isolation insulating structure SIS may extend in the direction of the minor axis AX1 to be located between the first end portion CH1[E1] of the first channel portion CH1 and the first end portion CH2[E1] of the second channel portion CH2. The isolation insulating structure SIS may extend into the third insulating layer IL3.

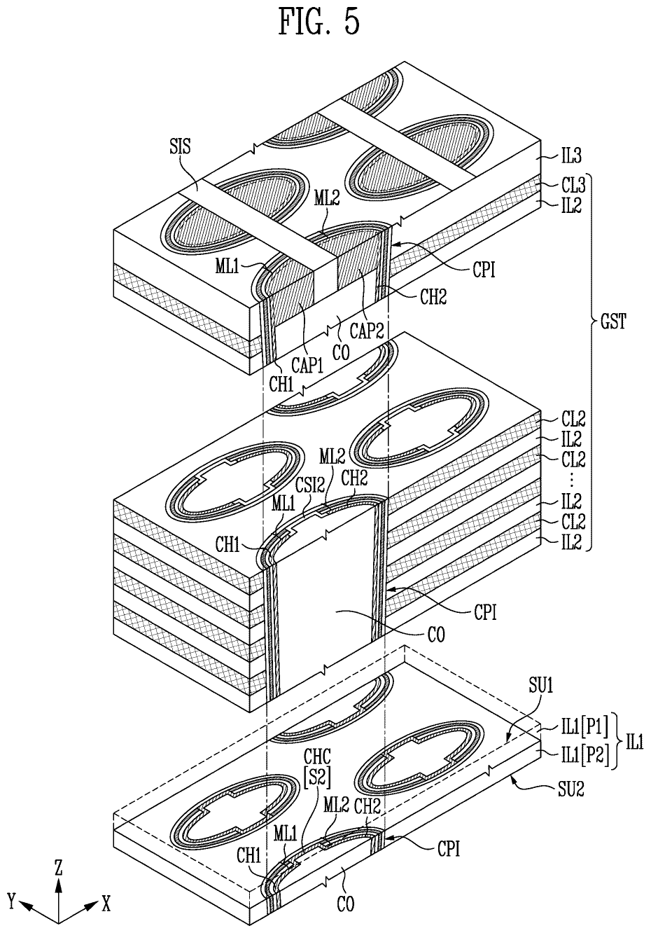

FIG. 5 is an exploded perspective view illustrating the semiconductor memory device as shown in FIGS. 2A and 2B.

Referring to FIG. 5, the first insulating layer IL1 includes a first portion IL1[P1] adjacent to the first surface SU1 and a second portion IL1[P2] adjacent to the second surface SU2. The cross-section of the cell pillar structure CPI in the first insulating layer IL1 as shown in FIGS. 4A and 5 corresponds to the cross-section of the cell pillar structure CPI in the second portion IL1[P2] of the first insulating layer IL1.

Referring to FIGS. 4A, 4B, 4C, 4D, and 5, the cell pillar structure CPI extends in the stacking direction, i.e., the Z-axis direction through the first insulating layer IL1, the plurality of second insulating layers IL2 and a plurality of conductive layers (e.g., CL2 and CL3) of the gate stack GST, and the third insulating layer IL3. The cell pillar structure CPI includes the semiconductor pillar SP, a first memory pattern ML1, a second memory pattern ML2, a first channel separation structure CSI1, a second channel separation structure CSI2, and a core insulating layer CO.

The core insulating layer CO of the cell pillar structure CPI is disposed in the central region of the hole H. The semiconductor pillar SP of the cell pillar structure CPI may surround the core insulating layer CO. The first channel portion CH1 and the second channel portion CH2 of the semiconductor pillar SP each extend along the sidewall of the core insulating layer CO and may extend in the Z-axis direction through the first insulating layer IL1 and the gate stack GST. Each of the first channel portion CH1 and the second channel portion CH2 protrudes farther in the Z-axis direction relative to the core insulating layer CO and extends through the third insulating layer IL3. The first channel portion CH1, the second channel portion CH2, and the core insulating layer CO may extend through the first insulating layer IL1.

Each of the first capping portion CAP1 and the second capping portion CAP2 of the semiconductor pillar SP overlaps with the core insulating layer CO in the Z-axis direction. The first side pattern CHC[S1] and the second side pattern CHC[S2] of the semiconductor pillar SP are arranged on the sidewall of the core insulating layer CO in the second portion IL1[P2] of the first insulating layer IL1.

The first channel separation structure CSI1 of the cell pillar structure CPI overlaps with the first side pattern CHC[S1] in the Z-axis direction, and the second channel separation structure CSI2 of the cell pillar structure CPI overlaps with the second side pattern CHC[S2] in the Z-axis direction. The first channel separation structure CSI1 and the second channel separation structure CSI2 include an insulating material, such as silicon oxide. The first channel separation structure CSI1 and the second channel separation structure CSI2 are arranged between the string channel region CH1[SC] of the first channel portion CH1 and the string channel region CH2[SC] of the second channel portion CH2 in the second section H[S2] of the hole H. The first channel separation structure CSI1 and the second channel separation structure CSI2 may protrude in the direction of the minor axis AX1 relative to the first channel portion CH1 and the second channel portion CH2. The first channel separation structure CSI1 and the second channel separation structure CSI2 may extend in the first portion IL1[P1] of the first insulating layer IL1. Each of the first channel isolation structure CSI1 and the second channel isolation structure CSI2 overlaps with the isolation insulating structure SIS in the Z-axis direction.

The isolation insulating structure SIS may be formed in a linear shape extending in the direction of the axial axis AX1 to overlap with the first channel isolation structure CSI1, the second channel isolation structure CSI2, and the core insulating layer CO.

The first memory pattern ML1 of the cell pillar structure CPI is disposed between the first sidewall SW1 of the semiconductor pillar SP and the gate stack GST, and the second memory pattern ML2 of the cell pillar structure CPI is disposed between the second sidewall SW2 of the semiconductor pillar SP and the gate stack GST. The first memory pattern ML1 extends between the first insulating layer IL1 and the first channel portion CH1, and the second memory pattern ML2 extends between the first insulating layer IL1 and the second channel portion CH2. The first memory pattern ML1 and the second memory pattern ML2 may extend in the Z-axis direction through the third insulating layer IL3. Each of the first memory pattern ML1 and the second memory pattern ML2 may include a tunnel insulating layer, a data storage layer, and a blocking insulating layer BI.

The tunnel insulating layer may include an oxide, such as silicon dioxide (SiO₂). The tunnel insulating layer is between the semiconductor pillar SP and the gate stack GST. The tunnel insulating layer is separated into a first tunnel insulating pattern TI1 of the first memory pattern ML1 and a second tunnel insulating pattern TI2 of the second memory pattern ML2 in the second section H[S2] of the hole H and the first portion IL1[P1] of the first insulation layer by the first channel separation structure CSI1 and the second channel separation structure CSI2. The first tunnel insulating pattern TI1 and the second tunnel insulating pattern TI2 may extend through the second portion IL1[P2] of the first insulating layer and the third insulating layer IL3. The first tunnel insulating pattern TI1 and the second tunnel insulating pattern TI2 may be separated from each other in the second portion IL1[P2] of the first insulating layer by the first side pattern CHC[S1] and the second side pattern CHC[S2]. The first tunnel insulating pattern TI1 and the second tunnel insulating pattern TI2 may be separated from each other in the third insulating layer IL3 by the isolation insulating structure SIS.

The data storage layer may be formed as a material layer capable of storing data which changes by using Fowler-Nordheim tunneling. In an embodiment, the data storage layer may be formed as a charge trap insulating layer or an insulating layer including conductive nanodots. The charge trap insulating layer may include a silicon nitride layer. The data storage layer is between the tunnel insulating layer and the gate stack GST. The data storage layer is separated into a first data storage pattern DS1 of the first memory pattern ML1 and a second data storage pattern DS2 of the second memory pattern ML2 in the second section H[S2] of the hole H and in the first portion IL1[P1] of the first insulating layer by the first channel separation structure CSI1 and the second channel separation structure CSI2. The first data storage pattern DS1 and the second data storage pattern DS2 may extend through the second portion IL1[P2] of the first insulating layer and the third insulating layer IL3. The first data storage pattern DS1 and the second data storage pattern DS2 may be separated from each other in the second portion IL1[P2] of the first insulating layer by a first side pattern CHC[S1] and a second side pattern CHC[S2]. The first data storage pattern DS1 and the second data storage pattern DS2 may be separated from each other in the third insulating layer IL3 by the isolation insulating structure SIS.

The blocking insulating layer BI may include an oxide, such as silicon dioxide (SiO₂), a high-dielectric insulating material having a high dielectric constant compared to the silicon dioxide, and the like. The high-dielectric insulating material may include an aluminum oxide layer, a hafnium oxide layer, or the like. The blocking insulating layer BI is between the data storage layer and the gate stack GST. The blocking insulating layer BI may extend continuously along the outer walls of the first data storage pattern DS1, the second data storage pattern DS2, the first channel separation structure CSI1, and the second channel separation structure CSI2 in each of the second section H[S2] of the hole H and the first portion IL1[P1] of the first insulating layer IL1. The blocking insulating layer BI may extend in the Z-axis direction through the second portion IL1[P2] of the first insulation layer and the third insulation layer IL3. The blocking insulating layer BI may extend continuously along the outer walls of the first data storage pattern DS1, the second data storage pattern DS2, the first side pattern CHC[S1], and the second side pattern CHC[S2] in the second portion IL1[P2] of the first insulation layer. In an embodiment, the blocking insulating layer BI may be formed as a ring shape in the XY plane in of each of the first section H[S1] and the second section H[S2] of the hole H. The separation isolation insulating structure SIS may extend in the direction of the minor axis AX1 through the blocking insulating layer BI in the third insulation layer IL3.

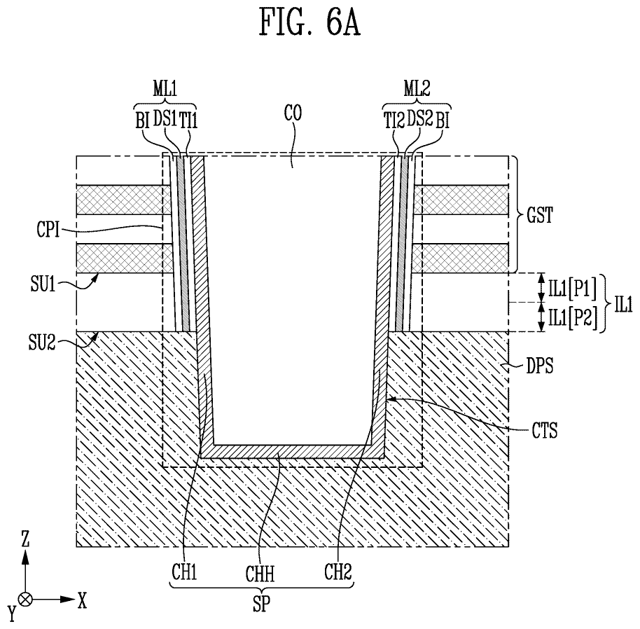

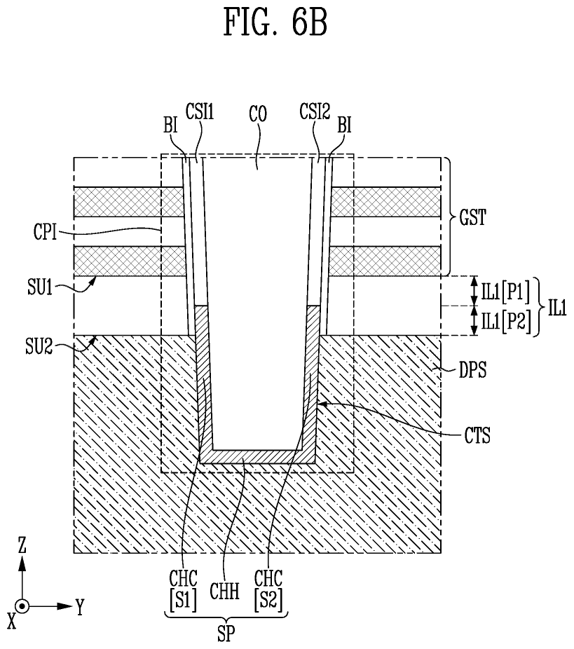

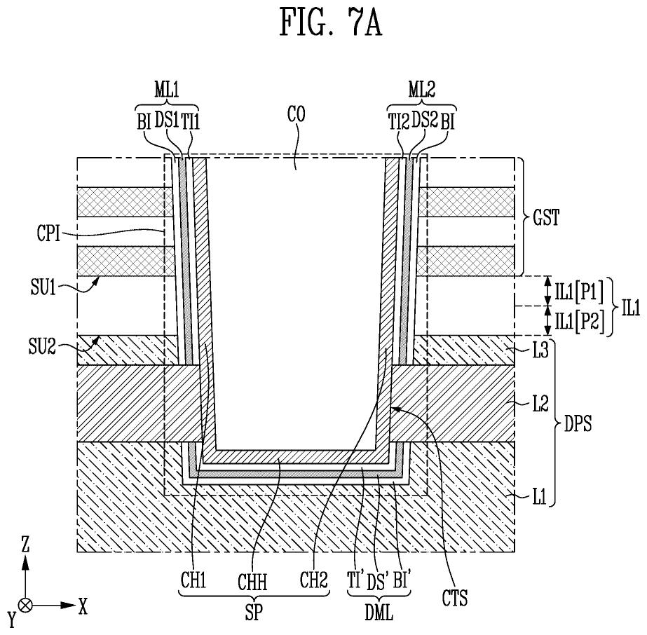

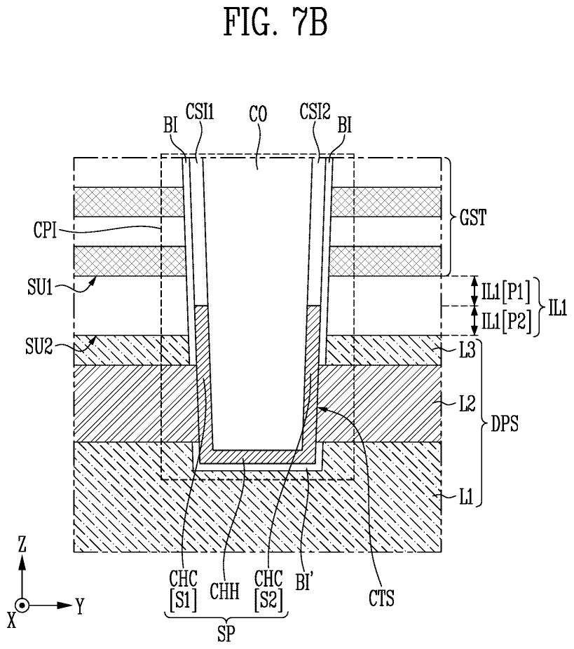

The semiconductor pillar SP may include a contact surface in contact with the doped semiconductor structure DPS as shown in FIG. 2A or 2B. The contact surface may have various designs. A contact surface according to embodiments of the present disclosure is described below with reference to FIGS. 6A, 6B, 7A, and 7B.

FIG. 6A is a cross-sectional view showing various configurations of a semiconductor memory device according to an embodiment of the present disclosure, taken along the major axis of the hole as shown in FIGS. 4A to 4C, and FIG. 6B is a cross-sectional view showing various configurations of the semiconductor memory device, taken along the minor axis of the hole as shown in FIGS. 4A to 4C.

FIG. 7A is a cross-sectional view showing various configurations of a semiconductor memory device according to an embodiment of the present disclosure, taken along the major axis of the hole as shown in FIGS. 4A to 4C, and FIG. 7B is a cross-sectional view showing various configurations of the semiconductor memory device taken along the minor axis of the hole as shown in FIGS. 4A to 4C.

Referring to FIGS. 6A, 6B, 7A, and 7B, the first surface SU1 of the first insulating layer IL1 is configured as the first portion IL1[P1], and the second surface SU2 of the first insulating layer IL1 is configured as the second portion IL1[P2]. The gate stack GST is disposed over the first surface SU1, and the doped semiconductor structure DPS is disposed over the second surface SU2.

The core insulating layer CO and the semiconductor pillar SP of the cell pillar structure CPI extend through the first surface SU1 and the second surface SU2 of the gate stack GST and the first insulating layer IL1. The core insulating layer CO and the semiconductor pillar SP may extend into the interior of the doped semiconductor structure DPS.

The first channel portion CH1 and the second channel portion CH2 of the semiconductor pillar SP extend in the Z-axis direction through the gate stack GST and the first insulating layer IL1. The first channel portion CH1 and the second channel portion CH2 may extend into the doped semiconductor structure DPS. The first side pattern CHC[S1] and the second side pattern CHC[S2], which constitute the connecting portion of the semiconductor pillar SP, extend from the inside of the doped semiconductor structure DPS to the inside of the second portion IL1[P2] of the first insulating layer IL1. The semiconductor pillar SP may further include a horizontal portion CHH. The horizontal portion CHH may extend in parallel to the XY plane from each of the first channel portion CH1, the second channel portion CH2, the first side pattern CHC[S1], and the second side pattern CHC[S2]. The horizontal portion CHH may be surrounded by the first channel portion CH1, the second channel portion CH2, the first side pattern CHC[S1], and the second side pattern CHC[S2]. The horizontal portion CHH may be disposed on one surface of the core insulating layer CO opposite the isolation insulating structure SIS, the first capping portion CAP1, and the second capping portion CAP2 as shown in FIG. 5.

The first channel separation structure CSI1 and the second channel separation structure CSI2 of the cell pillar structure CPI are arranged on the first side pattern CHC[S1] and the second side pattern CHC[S2], respectively. The first channel separation structure CSI1 and the second channel separation structure CSI2 extend in the Z-axis direction through the first portion IL1[P1] of the first insulating layer IL1 and the gate stack GST.

The first tunnel insulating pattern TI1 and the first data storage pattern DS1 of the first memory pattern ML1 are arranged between the first channel portion CH1 and the gate stack GST. The first tunnel insulating pattern TI1 and the first data storage pattern DS1 extend between the first channel portion CH1 and the first insulating layer IL1. The second tunnel insulating pattern TI2 and the second data storage pattern DS2 of the second memory pattern ML2 are arranged between the second channel portion CH2 and the gate stack GST. The second tunnel insulating pattern TI2 and the second data storage pattern DS2 extend between the second channel portion CH2 and the first insulating layer IL1. In an embodiment, each of the first tunnel insulating pattern TI1 and the first data storage pattern DS1 may extend between each of the first portion IL1[P1] and the second portion IL1[P2] of the first insulating layer IL1 and the first channel portion CH1, and each of the second tunnel insulating pattern TI2 and the second data storage pattern DS2 may extend between each of the first portion IL1[P1] and the second portion IL1[P2] of the first insulation layer IL1 and the second channel portion CH2. The blocking insulating layer BI extends along the outer wall of each of the first data storage pattern DS1, the second data storage pattern DS2, the first channel separation structure CSI1, and the second channel separation structure CSI2. The blocking insulating layer BI extends along the outer wall of each of the first channel portion CH1, the second channel portion CH2, the first side pattern CHC[S1], and the second side pattern CHC[S2] in the second portion IL1[P2] of the first insulation layer IL1.

The doped semiconductor structure DPS may form a contact surface CTS with at least one of the first channel portion CH1, the second channel portion CH2, the first side pattern CHC[S1], the second side pattern CHC[S2], and the horizontal portion CHH of the semiconductor pillar SP.

Referring to FIGS. 6A and 6B, in an embodiment, the doped semiconductor structure DPS may include an n-type impurity region or both an n-type impurity region and a p-type impurity region. The contact surface CTS of the doped semiconductor structure DPS may include a plurality of n-type impurities as majority carriers. The doped semiconductor structure DPS may include the contact surface CTS in contact with the second end portion CH1[E2] of the first channel portion CH1 as shown in FIGS. 3 and 4A, the second end portion CH2[E2] of the second channel portion CH2 as shown in FIGS. 3 and 4A, the first side pattern CHC[S1], the second side pattern CHC[S2], and the horizontal portion CHH.

Referring to FIGS. 7A and 7B, in an embodiment, the doped semiconductor structure DPS may include a first doped semiconductor layer L1, a second doped semiconductor layer L2, and a third doped semiconductor layer L3 stacked in the Z-axis direction. The cell pillar structure CPI may extend through the third doped semiconductor layer L3 of the doped semiconductor structure DPS and may extend into the first doped semiconductor layer L1.

Each of the first doped semiconductor layer L1, the second doped semiconductor layer L2, and the third doped semiconductor layer L3 may include n-type impurities, p-type impurities, or a mixture thereof. In an embodiment, each of the first doped semiconductor layer L1, the second doped semiconductor layer L2, and the third doped semiconductor layer L3 may include n-type impurities as majority carriers. Embodiments of the present disclosure are not limited thereto. In an embodiment, the doped semiconductor structure DPS may form an n-type impurity region including n-type impurities as majority carriers and a p-type impurity region including p-type impurities as majority carriers. For example, the second doped semiconductor layer L2 may form an n-type impurity region, and one or both of the first doped semiconductor layer L1 and the third doped semiconductor layer L3 may form a p-type impurity region.

The cell pillar structure CPI may include a dummy memory pattern DML between the first doped semiconductor layer L1 of the doped semiconductor structure DPS and the semiconductor pillar SP. The dummy memory pattern DML may include a dummy tunnel insulating layer TI′, which includes the same material as the first and second tunnel insulating patterns TI1 and TI2, a dummy data storage layer DS′, which includes the same material as the first and second data storage patterns DS1 and DS2, and a dummy blocking insulating layer BI′, which includes the same material as the blocking insulating layer BI. The dummy memory pattern DML may be between the horizontal portion CHH of the semiconductor pillar SP and the first doped semiconductor layer L1. The horizontal portion CHH of the semiconductor pillar SP may extend through the dummy tunnel insulating layer TI′ and the dummy data storage layer DS′ of the dummy memory pattern DML to contact the dummy blocking insulating layer BI′. The contact surface between the horizontal portion CHH and the dummy blocking insulating layer BI′ may extend along the direction of the minor axis AX1 of the hole as shown in FIGS. 4A to 4C.

Each of the first memory pattern ML1 and the second memory pattern ML2 of the cell pillar structure CPI may extend between the semiconductor pillar SP and the third doped semiconductor layer L3 of the doped semiconductor structure DPS. The blocking insulating layer BI of the cell pillar structure CPI may extend between each of the first side pattern CHC[S1] and the second side pattern CHC[S2] of the semiconductor pillar SP and the third doped semiconductor layer L3 of the doped semiconductor structure DPS.

The contact surface CTS of the doped semiconductor structure DPS may be formed on the second doped semiconductor layer L2. The second doped semiconductor layer L2 may include the contact surface CTS contacting the first channel portion CH1, the second channel portion CH2, the first side pattern CHC[S1], and the second side pattern CHC[S2]. The contact surface CTS may be between the first doped semiconductor layer L1 and the third doped semiconductor layer L3.

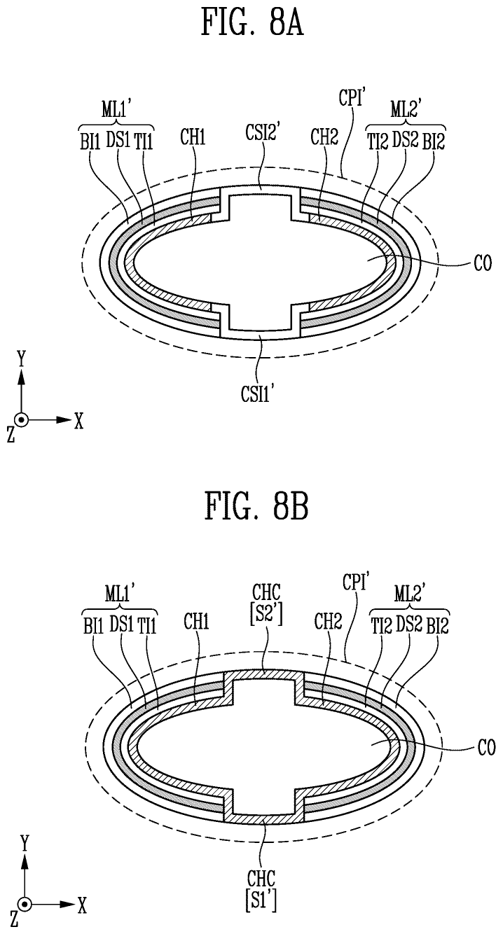

FIGS. 8A and 8B are plan views illustrating a cross-section of a cell pillar structure CPI′ according to embodiments of the present disclosure.

Referring to FIGS. 8A and 8B, as described above with reference to FIGS. 4A to 4C, the cell pillar structure CPI′ includes the core insulating layer CO, the first channel portion CH1, the second channel portion CH2, a first side pattern CHC[S1′], and a second side pattern CHC[S2′]. As described above with reference to FIGS. 4A to 4C, a first memory pattern ML1′ of the cell pillar structure CPI′ includes the first tunnel insulating pattern TI1 and the first data storage pattern DS1, and a second memory pattern ML2′ of the cell pillar structure CPI′ includes the second tunnel insulating pattern TI2 and the second data storage pattern DS2.

Referring to FIG. 8A, each of a first channel separation structure CSI1′ and a second channel separation structure CSI2′ of the cell pillar structure CPI′ is located between the first channel portion CH1 and the second channel portion CH2 in the XY plane. Each of the first channel separation structure CSI1′ and the second channel separation structure CSI2′ extends in the XY plane in the direction of the minor axis (AX1 in FIG. 4A) of the hole, is disposed between the first tunnel insulating pattern TI1 and the second tunnel insulating pattern TI2 and between the first data storage pattern DS1 and the second data storage pattern DS2, and protrudes through the blocking insulating layer of the cell pillar structure CPI′. The blocking insulating layer may be separated by the first channel separation structure CSI1′ and the second channel separation structure CSI2′ into a first blocking insulating pattern BI1 of the first memory pattern ML1′ and a second blocking insulating pattern BI2 of the second memory pattern ML2′.

Referring to FIG. 8B, each of the first side pattern CHC[S1′] and the second side pattern CHC[S2′] constituting the connecting portion of the semiconductor pillar is located between the first channel portion CH1 and the second channel portion CH2 in the XY plane. Each of the first side pattern CHC[S1′] and the second side pattern CHC[S2′] extends in the XY plane in the direction of the minor axis (AX1 in FIG. 4A) of the hole, is disposed between the first tunnel insulating pattern TI1 and the second tunnel insulating pattern TI2 and between the first data storage pattern DS1 and the second data storage pattern DS2, and protrudes through the blocking insulating layer of the cell pillar structure CPI′. The blocking insulating layer may be separated into the first blocking insulating pattern BI1 of the first memory pattern ML1′ and the second blocking insulating pattern BI2 of the second memory pattern ML2′ by the first side pattern CHC[S1′] and the second side pattern CHC[S2′].

Various methods of manufacturing a semiconductor memory device according to embodiments of the present disclosure are described below.

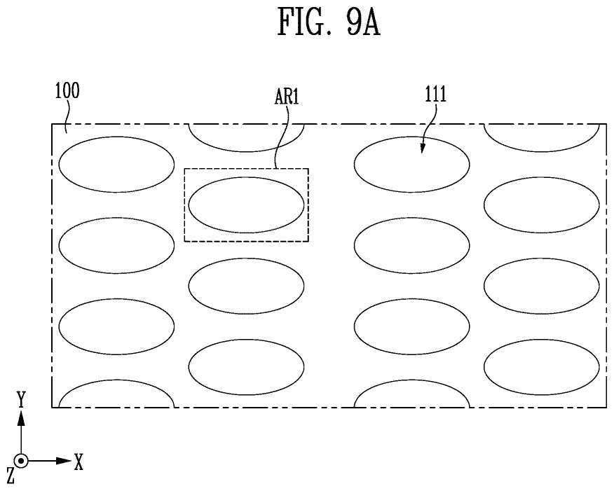

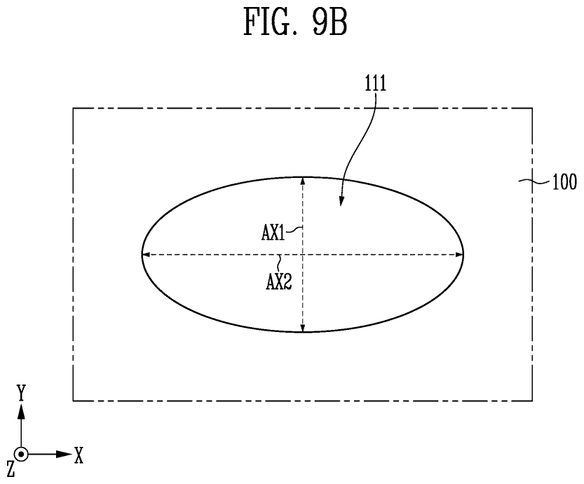

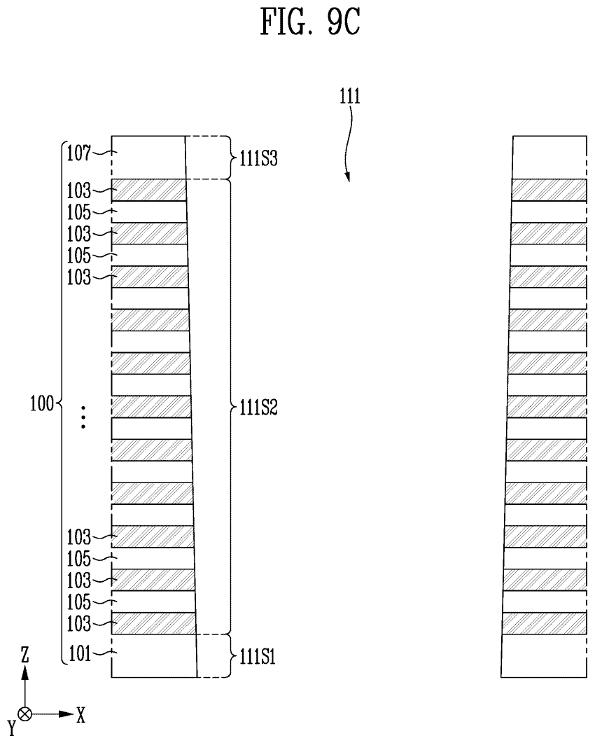

FIGS. 9A, 9B, and 9C are diagrams illustrating a preliminary stack and a hole according to embodiments of the present disclosure.

FIG. 9A is a plan view illustrating a preliminary stack 100 and a plurality of holes 111, and FIG. 9B is an enlarged view of an area AR1 as shown in FIG. 9A.

Referring to FIGS. 9A and 9B, the preliminary stack 100 may be penetrated by the plurality of holes 111. Each of the holes 111 has a structure including the minor axis AX1 and the major axis AX2 which intersect each other in the XY plane. In an embodiment, the holes 111 may have an elliptical shape in the XY plane.

FIG. 9C is a cross-sectional view showing the preliminary stack 100 and the hole 111 by cutting the preliminary stack 100 along the major axis AX2 as shown in FIG. 9B.

Referring to FIGS. 9A, 9B, and 9C, in an embodiment, forming the preliminary stack 100 includes forming a lower insulating layer 101 extending in parallel to the XY plane, stacking a plurality of first material layers 103 and a plurality of second material layers 105 in a stacking direction crossing the XY plane (e.g., a Z-axis direction), and forming an upper insulating layer 107 over top of the stack of the plurality of first material layers 103 and the plurality of second material layers 105. Each of the plurality of first material layers 103 is alternately stacked with each of the plurality of second material layers 105 in the stacking direction.

Though not shown, the lower insulating layer 101 may be formed over a lower structure (not shown). In an embodiment, the lower structure may include the semiconductor substrate SUB, the peripheral circuit structure PCS, and the doped semiconductor structure DPS as shown in FIG. 2A. In another embodiment, the lower structure may include the semiconductor substrate SUB and the peripheral circuit structure PCS as shown in FIG. 2A and a preliminary semiconductor structure. The preliminary semiconductor structure may include the first doped semiconductor layer L1 and the third doped semiconductor layer L3 shown in FIGS. 7A and 7B, and a sacrificial structure therebetween. The sacrificial structure may be replaced with the second doped semiconductor layer L2 as shown in FIGS. 7A and 7B in a subsequent process. In another embodiment, the lower structure may be a sacrificial substrate formed using a silicon wafer or the like.

Each of the plurality of first material layers 103 and the plurality of second material layers 105 extends in the XY plane. The plurality of first material layers 103 may include a sacrificial insulating material having an etch selectivity for the lower insulating layer 101, the plurality of second material layers 105, and the upper insulating layer 107. In an embodiment, the sacrificial insulating material may include a silicon nitride layer. Each of the lower insulating layer 101, the plurality of second material layers 105, and the upper insulating layer 107 may include an insulating material, such as a silicon oxide layer and a silicon oxynitride layer. In the Z-axis direction which is the stacking direction, each of the lower insulating layer 101 and the upper insulating layer 107 may be thicker than each of the second material layers 105.

The process of forming the hole 111 includes a process of forming a mask pattern (not shown) using a photolithography process and etching the preliminary stack 100 using the mask pattern as an etch barrier. The mask pattern may be removed after a preliminary cell pillar structure is formed in a subsequent process. The hole 111 includes a first section 111S1, a second section 111S2 coupled to the first section 111S1, and a third section 111S3 coupled to the second section 111S2. The first section 111S1 extends through the lower insulating layer 101. The second section 111S2 extends through the plurality of first material layers 103 and the plurality of second material layers 105. The third section 111S3 extends through the upper insulating layer 107. Each of the first section 111S1, the second section 111S2, and the third section 111S3 of the hole 111 may have an elliptical shape in the XY plane.

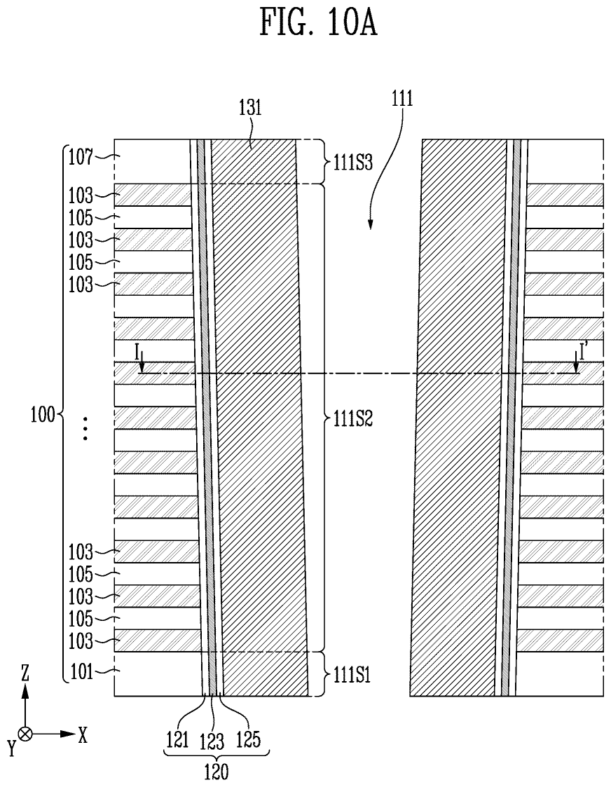

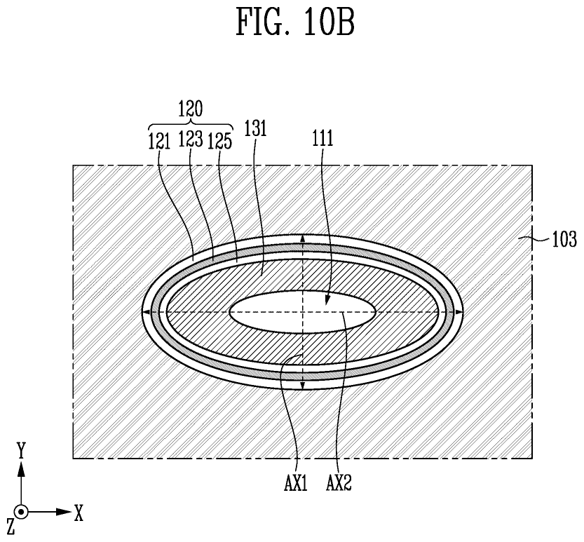

FIGS. 10A, 10B, 11A, 11B, 12A, 12B, 13A, 13B, 13C, 14A, 14B, and 14C are diagrams illustrating various configurations formed in a hole using a method of manufacturing a semiconductor memory device according to embodiments of the present disclosure.

FIG. 10A is a cross-sectional view showing the various configurations formed in the hole by cutting the preliminary stack 100 along the major axis AX2 of the hole 111 as shown in FIG. 9B. FIG. 10B is a plan view showing the various configurations formed in the hole by cutting the preliminary stack 100 along line I-I′ in FIG. 10A.

Referring to FIGS. 10A and 10B, a memory layer 120 and a seed barrier layer 131 may be formed sequentially on the interior of the hole 111.

The memory layer 120 may be disposed on a sidewall of the lower insulating layer 101 adjacent to the hole 111, and may extend into the second section 111S2 and third section 111S3 of the hole 111. The memory layer 120 may include a blocking insulating layer 121, a data storage layer 123, and a tunnel insulating layer 125. The blocking insulating layer 121 is disposed on a sidewall of the lower insulating layer 101 and extends into the second section 111S2 and the third section 111S3 of the hole 111. The blocking insulating layer 121 may include one or both of a silicon dioxide and a high dielectric insulating material having a high dielectric constant compared to a silicon dioxide. The data storage layer 123 is disposed on an inner wall of the blocking insulating layer 121. The data storage layer 123 may include a charge trap insulating layer of a silicon nitride or the like. The tunnel insulating layer 125 is disposed on the inner wall of the data storage layer 123. The tunnel insulating layer 125 may include silicon dioxide or the like.

The seed barrier layer 131 is formed along a surface of the tunnel insulating layer 125. The seed barrier layer 131 may have an etch selectivity for the tunnel insulating layer 125. In an embodiment, the seed barrier layer 131 may include silicon. When the seed barrier layer 131 is deposited, the deposition thickness is controlled to be greater in the direction of the major axis AX2 than in the direction of the minor axis AX1 of the hole 111.

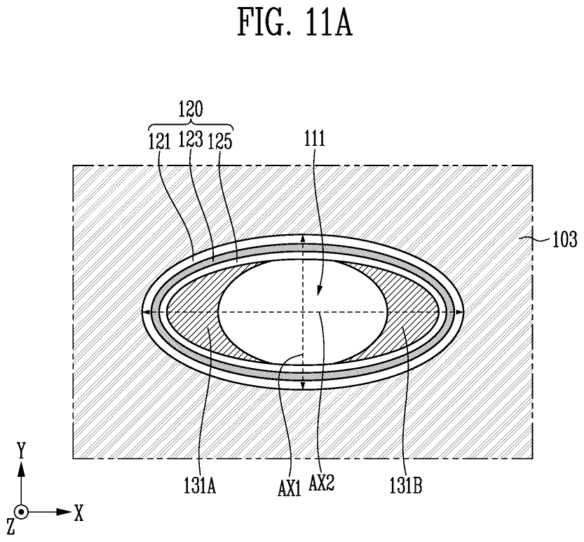

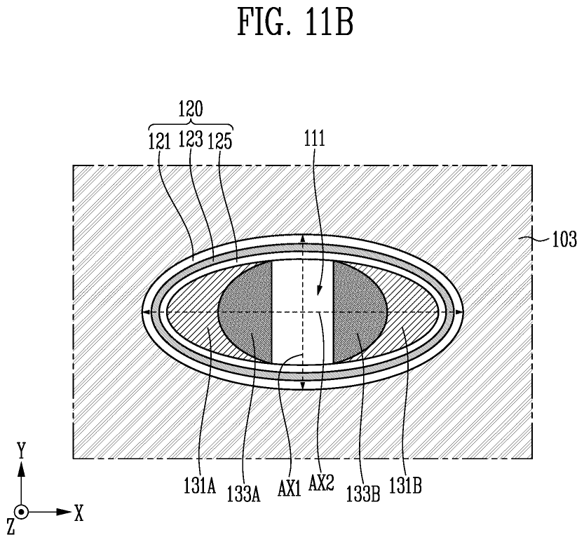

FIGS. 11A and 11B are plan views illustrating various configurations formed in the hole, taken along line I-I′ in FIG. 10A.

Referring to FIG. 11A, by removing a portion of the seed barrier layer 131 as shown in FIG. 10B through the hole 111, the seed barrier layer 131 is separated into a first seed barrier pattern 131A and a second seed barrier pattern 131B. The first seed barrier pattern 131A and the second seed barrier pattern 131B are defined based on the minor axis AX1 of the hole 111 and are spaced apart from each other in the direction of the major axis AX2. A portion of the memory layer 120 overlapping with the minor axis AX1 is exposed between the first seed barrier pattern 131A and the second seed barrier pattern 131B.

Referring to FIG. 11B, a first growth barrier pattern 133A and a second growth barrier pattern 133B are formed on the inner walls of the first seed barrier pattern 131A and the second seed barrier pattern 131B, respectively. The first growth barrier pattern 133A and the second growth barrier pattern 133B may be formed by a selective growth method. In an embodiment, the first growth barrier pattern 133A and the second growth barrier pattern 133B may be selectively grown toward the intersection of the minor axis AX1 and the major axis AX2 from the inner walls of the first seed barrier pattern 131A and the second seed barrier pattern 131B, respectively, by a selective poly-silicon growth method. The first growth barrier pattern 133A and the second growth barrier pattern 133B are defined based on the minor axis AX1 of the hole 111 and are spaced apart from each other in the direction of the major axis AX2. A portion of the memory layer 120 overlapping with the minor axis AX1 is exposed between the first growth barrier pattern 133A and the second growth barrier pattern 133B.

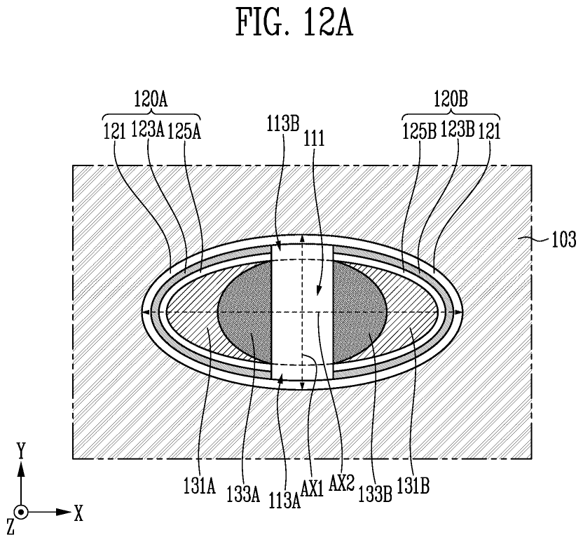

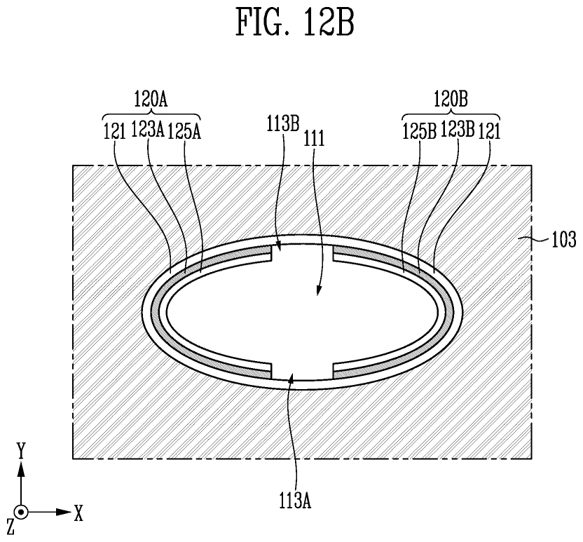

FIGS. 12A and 12B are plan views of a recess formed in the hole, taken along line I-I′ shown in FIG. 10A.

Referring to FIG. 12A, a first recess 113A and a second recess 113B may be formed by etching a portion of the memory layer 120 exposed between the first growth barrier pattern 133A and the second growth barrier pattern 133B shown in FIG. 11B. In an embodiment, the first recess 113A and the second recess 113B may be formed by etching some areas of the tunnel insulating layer and some areas of the data storage layer overlapping with the minor axis AX1 of the hole 111. A portion of the inner wall of the blocking insulating layer 121 may be exposed by the first recess 113A and the second recess 113B.

The tunnel insulating layer is separated into a first tunnel insulating pattern 125A and a second tunnel insulating pattern 125B by the first recess 113A and the second recess 113B. The data storage layer is separated into a first data storage pattern 123A and a second data storage pattern 123B by the first recess 113A and the second recess 113B. Thus, the memory layer 120 as shown in FIG. 11B may be divided into a first memory pattern 120A including the first tunnel insulating pattern 125A and the first data storage pattern 123A, and a second memory pattern 120B including the second tunnel insulating pattern 125B and the second data storage pattern 123B. The blocking insulating layer 121 might not be separated by the first recess 113A and the second recess 113B. The blocking insulating layer 121 may extend continuously in the XY plane to surround the outer wall of the first data storage pattern 123A as well as the outer wall of the second memory pattern 120B.

Referring to FIG. 12B, the first seed barrier pattern 131A, the second seed barrier pattern 131B, the first growth barrier pattern 133A, and the second growth barrier pattern 133B as shown in FIG. 12A are selectively removed. As a result, the inner walls of the first memory pattern 120A and the second memory pattern 120B may be exposed through the hole 111.

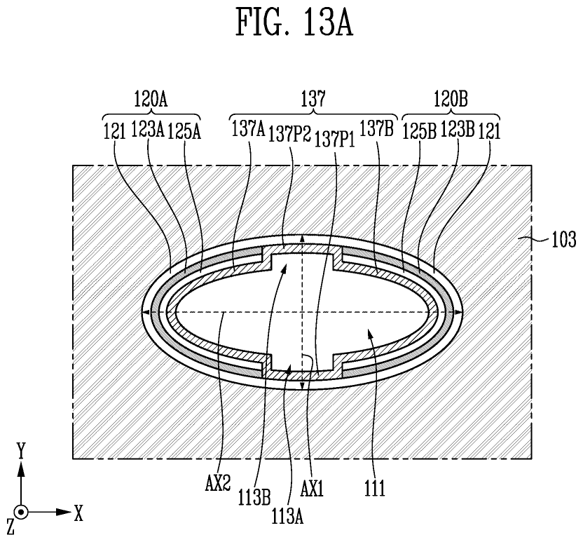

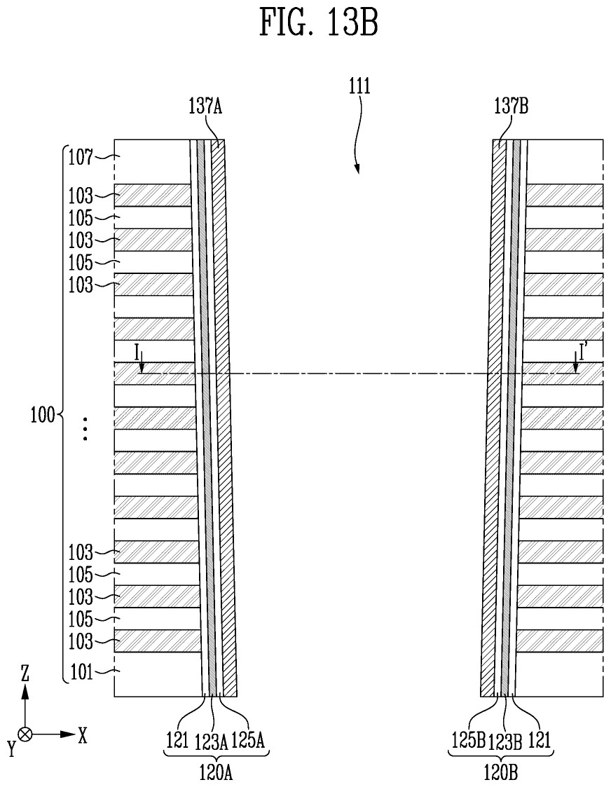

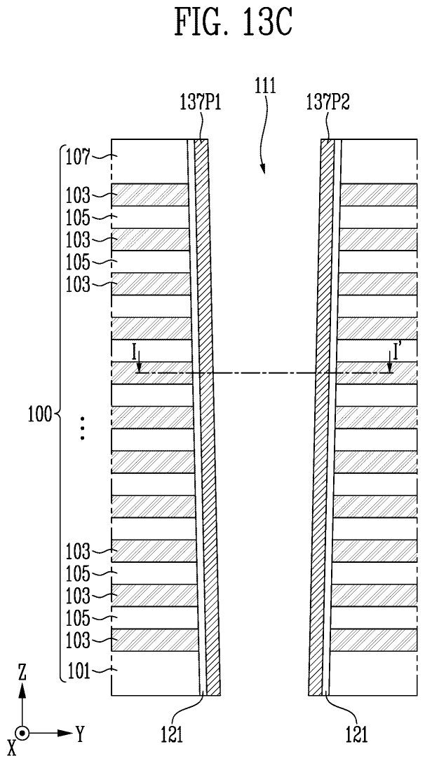

FIGS. 13A, 13B, and 13C are diagrams illustrating a channel layer 137 in the hole 111. FIG. 13A is a plan view of various configurations taken along line I-I′ in FIG. 13B. FIG. 13B is a cross-sectional view of various configurations taken along the major axis AX2 in FIG. 13A. FIG. 13C is a cross-sectional view of various configurations taken along the minor axis AX1 in FIG. 13A.

Referring to FIGS. 13A, 13B, and 13C, the channel layer 137 is formed on an exposed inner wall of each of the first memory pattern 120A, the blocking insulating layer 121, and the second memory pattern 120B. The channel layer 137 may include silicon (Si), germanium (Ge), or a mixture thereof.

The channel layer 137 includes a first channel portion 137A, a second channel portion 137B, a first protrusion 137P1, and a second protrusion 137P2. The first channel portion 137A is part of the channel layer 137 disposed on the inner wall of the first tunnel insulating pattern 125A of the first memory pattern 120A. The second channel portion 137B is part of the channel layer 137 disposed on the inner wall of the second tunnel insulating pattern 125B of the second memory pattern 120B. The first protrusion 137P1 is a portion of the channel layer 137 between the first channel portion 137A and the second channel portion 137B and protruding into the first recess 113A as shown in FIG. 12B. The second protrusion 137P2 is a portion of the channel layer 137 between the first channel portion 137A and the second channel portion 137B and protruding into the second recess 113B as shown in FIG. 12B. Each of the first protruding portion 137P1 and the second protruding portion 137P2 is disposed on the inner wall of the blocking insulating layer 121.

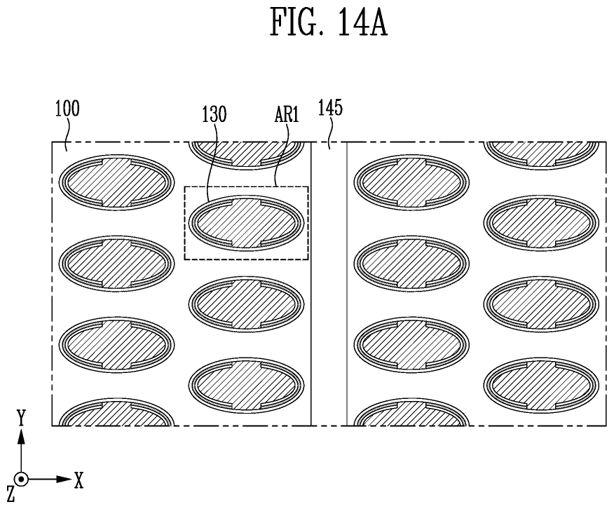

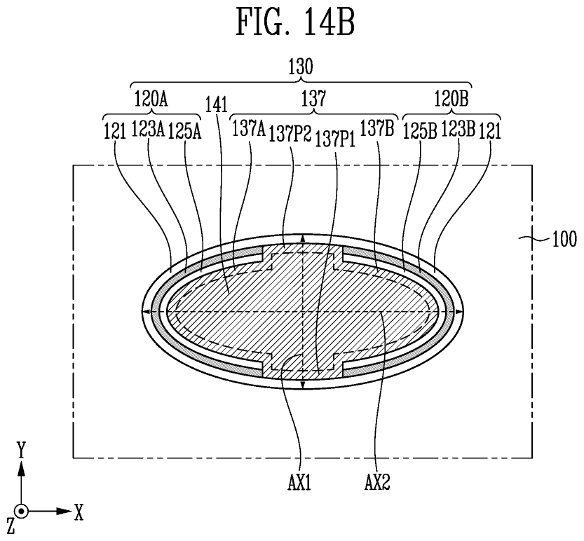

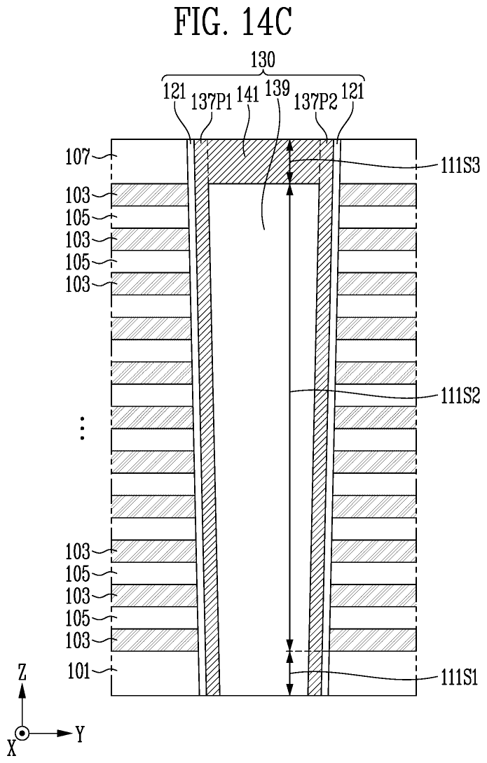

FIGS. 14A, 14B, and 14C are diagrams illustrating various configurations penetrating through a preliminary stack 100 according to embodiments of the present disclosure.

FIG. 14A is a plan view illustrating a preliminary cell pillar structure 130 and a slit 145 through the preliminary stack 100, FIG. 14B is an enlarged view of an area AR1 as shown in FIG. 14A, and FIG. 14C is a cross-sectional view illustrating the preliminary stack 100 and the preliminary cell pillar structure 130 by cutting the preliminary stack 100 along the minor axis AX1 in FIG. 14B.

Referring to FIGS. 14A, 14B, and 14C, a core insulating layer 139 and a capping semiconductor layer 141 are formed in the central region of the hole surrounded by the channel layer 137. As a result, the preliminary cell pillar structure 130 including the first memory pattern 120A, the second memory pattern 120B, the channel layer 137, the core insulating layer 139, and the capping semiconductor layer 141 may be formed.

In an embodiment, the core insulating layer 139 may fill a central region of each of the first section 111S1 and the second section 111S2 of the hole surrounded by the channel layer 137, and the capping semiconductor layer 141 may fill a central region of the third section 111S3 of the hole surrounded by the channel layer 137. Each of the core insulating layer 139 and the capping semiconductor layer 141 may include portions extending into the first recess 113A and the second recess 113B as shown in FIG. 13A.

Forming the core insulating layer 139 includes filling the central region of each of the first section 111S1, the second section 111S2, and the third section 111S3 of the hole with an insulating material and etching a portion of the insulating material to open the central region of the third section 111S3 of the hole. The capping semiconductor layer 141 is in the region where a portion of the insulating material is etched. According to an embodiment of the present disclosure, in the process of etching the portion of the insulating material, the channel layer 137 is not divided into channel portions but remains continuously surrounding the central region of each of the first section 111S1, the second section 111S2, and the third section 111S3 of the hole in the XY plane. Accordingly, in the process of etching the portion of the insulating material, the first tunnel insulating pattern 125A, the second tunnel insulating pattern 125B, and the blocking insulating layer 121 may be protected by the first protrusion 137P1 and the second protrusion 137P2 of the channel layer 137. For example, a portion of the channel layer 137 may be etched to divide the channel layer 137 into the channel portions prior to forming an insulating material for the core insulating layer 139. The channel etch region in which a portion of the channel layer 137 is etched may be filled with an insulating material for the core insulating layer 139 and then opened during the process of etching the portion of the insulating material to open the central region of the third section 111S3 of the hole. When the portion of the insulating material is etched, the first tunnel insulating pattern 125A, the second tunnel insulating pattern 125B, and the blocking insulating layer 121 may be damaged through the opened channel etch region. Therefore, in order to protect the first tunnel insulating pattern 125A, the second tunnel insulating pattern 125B, and the blocking insulating layer 121, additional processes may be performed in the hole, such as forming a protective layer in each of the first section 111S1, the second section 111S2, and the third section 111S3 of the hole after dividing the channel layer 137 into channel portions and before forming the core insulating layer 139. According to an embodiment of the present disclosure, because the core insulating layer 139 is formed while the channel layer 137 is not divided into channel portions, the first tunnel insulating pattern 125A, the second tunnel insulating pattern 125B, and the blocking insulating layer 121 may be protected through the first protrusion 137P1 and the second protrusion 137P2 of the channel layer 137, even when the addition process such as forming the protective layer in the hole is excluded.

The capping semiconductor layers 141 includes a doped semiconductor material. The capping semiconductor layers 141 may include silicon (Si), germanium (Ge), or mixtures thereof, and may be doped with n-type impurities, or both n-type impurities and p-type impurities. In an embodiment, the capping semiconductor layer 141 may include a doped silicon including n-type impurities as majority carriers. The n-type or p-type impurities in the capping semiconductor layer 141 may diffuse into the channel layer 137 adjacent to the capping semiconductor layer 141. The capping semiconductor layer 141 and the channel layer 137 may be integrated by heat treatment, such as laser annealing.

The preliminary stack 100 may be penetrated by the slit 145.

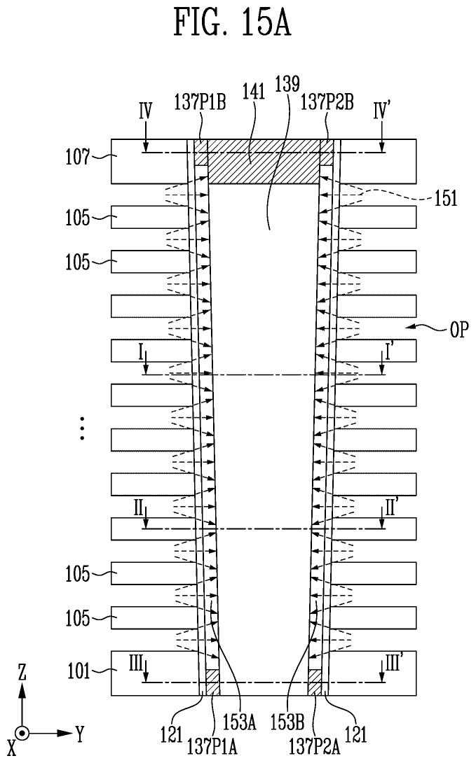

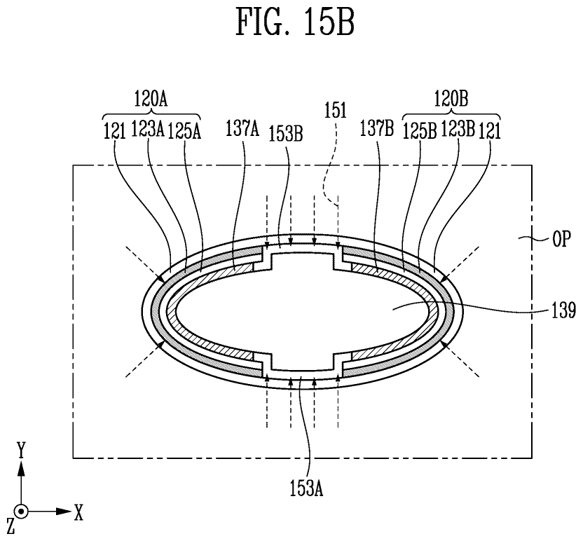

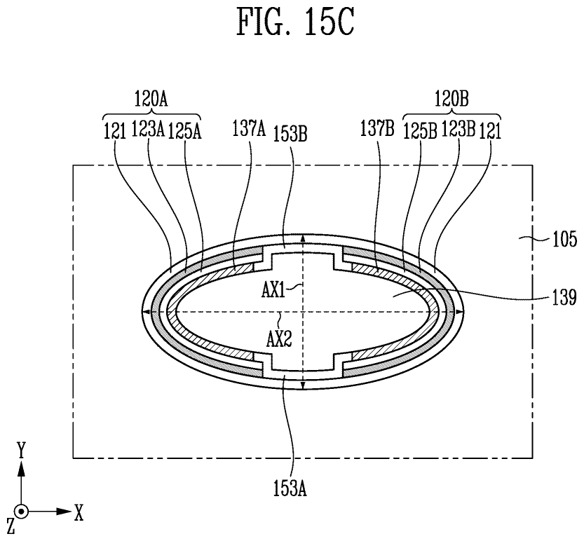

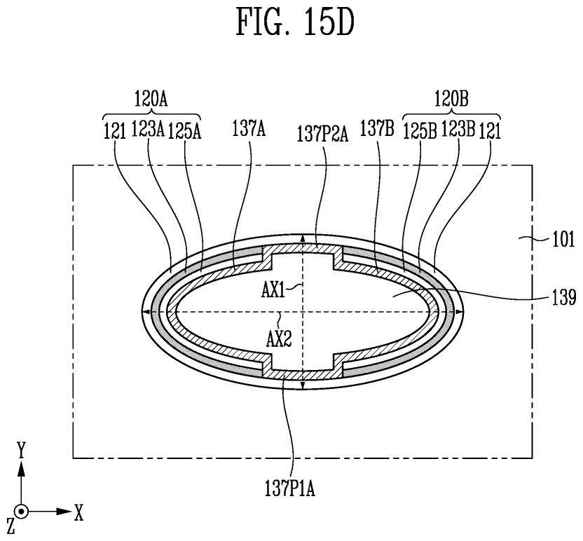

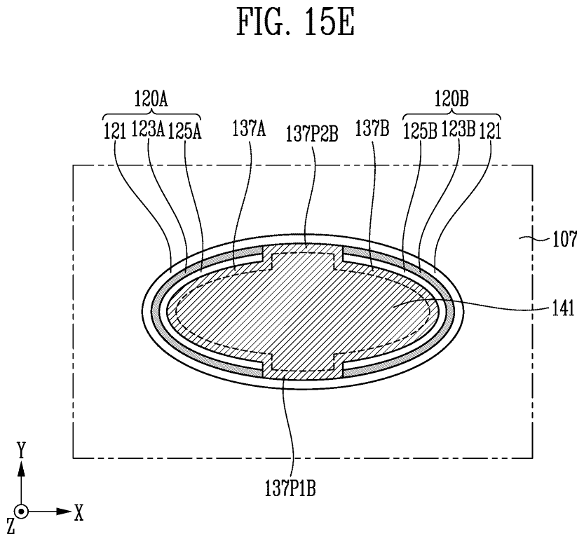

FIGS. 15A, 15B, 15C, 15D, and 15E are diagrams illustrating a channel separation structure and a connecting portion and a dummy portion of a channel layer formed using a method of manufacturing a semiconductor memory device according to an embodiment of the present disclosure.

FIG. 15A is a cross-sectional view showing a first channel separation structure 153A, a second channel separation structure 153B, a first side pattern 137P1A and a second side pattern 137P2A of the connecting portion, and a first dummy pattern 137P1B and a second dummy pattern 137P2B of the dummy portion, taken along the minor axis AX1 in FIG. 14B. FIG. 15B is a plan view showing the first channel separation structure 153A and the second channel separation structure 153B, taken along line I-I′ in FIG. 15A. FIG. 15C is a plan view showing the first channel separation structure 153A and the second channel separation structure 153B taken along line II-II′ in FIG. 15A. FIG. 15D is a plan view illustrating the first side pattern 137P1A and the second side pattern 137P2A taken along line III-III′ in FIG. 15A. FIG. 15E is a plan view illustrating the first dummy pattern 137P1B and the second dummy pattern 137P2B taken along line IV-IV′ in FIG. 15A.

Referring to FIGS. 15A, 15B, 15C, 15D, and 15E, a plurality of openings OP may be formed by selectively removing the plurality of first material layers 103 as shown in FIG. 14C through the slit 145 as shown in FIG. 14A. Subsequently, through the plurality of openings OP, the first protrusion 137P1 and the second protrusion 137P2 as shown in FIGS. 14B and 14C are replaced with the first channel separation structure 153A and the second channel separation structure 153B, respectively.

In an embodiment, the first channel separation structure 153A and the second channel separation structure 153B may be formed by oxidizing the first protrusion 137P1 and the second protrusion 137P2 shown in FIGS. 14B and 14C with an oxidizing agent 151 introduced through the plurality of openings OP. In an embodiment, the first channel separation structure 153A and the second channel separation structure 153B may be formed via a wet oxidation process. The oxidation process is performed with the first protrusion 137P1 and the second protrusion 137P2, as shown in FIGS. 14B and 14C, which are blocked by the blocking insulating layer 121. The blocking insulating layer 121 includes an oxide and does not block a reaction of the oxidizing agent 151 with each of the first protrusion 137P1 and the second protrusion 137P2 shown in FIGS. 14B and 14C. The oxidation process is carried out in a state in which the tunnel insulating layer is separated into the first tunnel insulating pattern 125A and the second tunnel insulating pattern 125B, with the first protrusion 137P1 and the second protrusion 137P2 as shown in FIGS. 14B and 14C protruding therebetween. Accordingly, the oxidation rate delay caused by the tunnel insulating layer may be reduced. The first data storage pattern 123A and the second data storage pattern 123B may block the reaction of the oxidizing agent 151 with the first channel portion 137A and the second channel portion 137B, respectively.

A portion of the first protrusion and a portion of the second protrusion formed on a sidewall of the lower insulating layer 101 which is relatively thicker than the plurality of second material layers 105 may form a connecting portion without being oxidized. The connecting portion includes the first side pattern 137P1A formed by the portion of the first protrusion and the second side pattern 137P2A formed by the portion of the second protrusion. The first side pattern 137P1A and the second side pattern 137P2A couple the first channel portion 137A and the second channel portion 137B in the lower insulating layer 101. According to an embodiment of the present disclosure, the first side pattern 137P1A and the second side pattern 137P2A are arranged in regions where the tunnel insulating layer and the data storage layer, respectively, are removed, so that the first channel portion 137A and the second channel portion 137B may protrude in the direction of the minor axis AX1 of the hole.

Another portion of the first protrusion and another portion of the second protrusion formed on the sidewall of the upper insulating layer 107, which is relatively thicker than the plurality of second material layers 105, might not be oxidized to form a dummy portion. The dummy portion includes the first dummy pattern 137P1B formed by another portion of the first protrusion and the second dummy pattern 137P2B formed by another portion of the second protrusion.

The first channel separation structure 153A extends continuously from the first side pattern 137P1A toward the first dummy pattern 137P1B, and the second channel separation structure 153B extends continuously from the second side pattern 137P2A toward the second dummy pattern 137P2B. Accordingly, each of the first channel separation structure 153A and the second channel separation structure 153B extends continuously in the Z-axis direction, which is the stacking direction, in the second section 111S2 of the hole as shown in FIG. 14C. Each of the first channel separation structure 153A and the second channel separation structure 153B is in contact with the blocking insulating layer 121.

The first channel portion 137A and the second channel portion 137B may be spaced apart from each other in the direction of the major axis AX2 of the hole in the second section 111S2 of the hole shown in FIG. 14C by the first channel separation structure 153A and the second channel separation structure 153B.

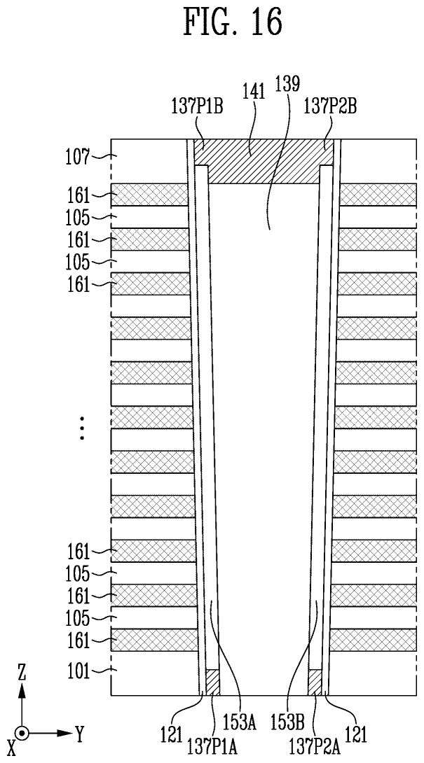

FIG. 16 is a cross-sectional view illustrating a plurality of conductive layers formed using a method of manufacturing a semiconductor memory device according to an embodiment of the present disclosure.

Referring to FIG. 16, a plurality of conductive layers 161 may be formed in the plurality of openings OP shown in FIGS. 15A and 15B. Each of the conductive layers 161 may include various conductive materials, such as doped semiconductor layers, metal layers, and the like. A doped semiconductor layer may include a doped silicon layer. The metal layer may include tungsten, copper, molybdenum, and the like. The conductive layer 161 may further include a metal nitride layer. The metal nitride layer may include titanium nitride, tantalum nitride, and the like. The metal nitride layer may be disposed on a surface of the blocking insulating layer 121 adjacent to the opening OP as shown in FIGS. 15A and 15B, and may extend over a surface of the lower insulating layer 101, a surface of the second material layer 105, or a surface of the upper insulation layer 107 adjacent to the opening OP.

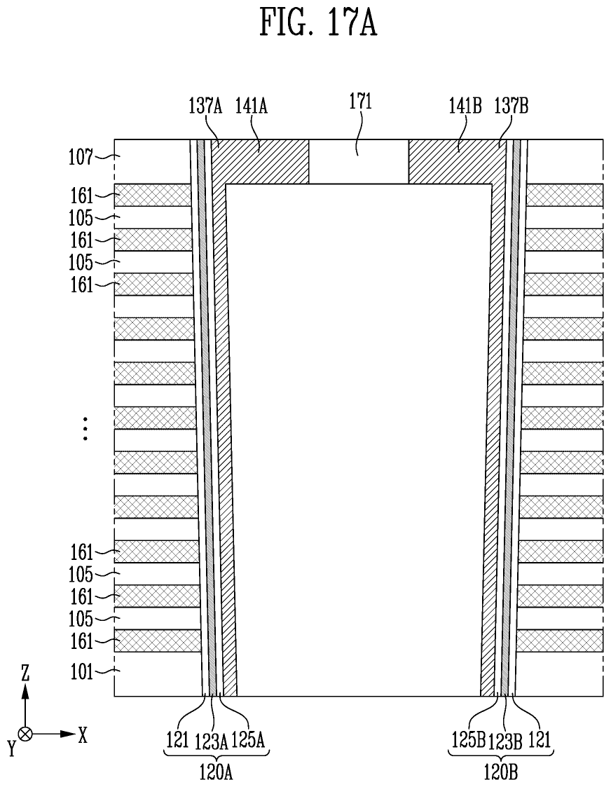

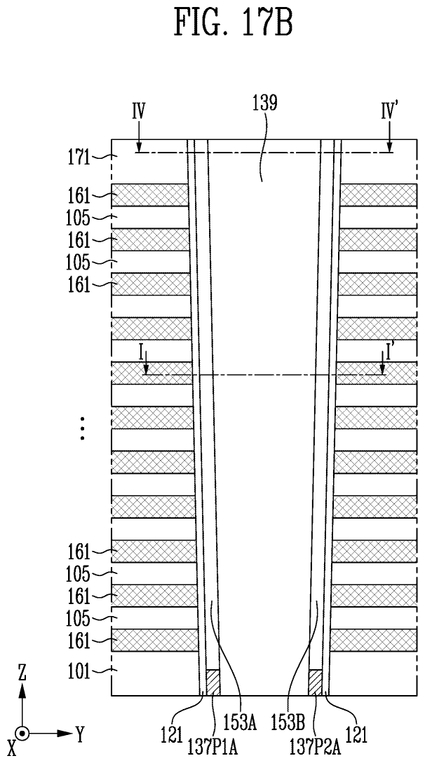

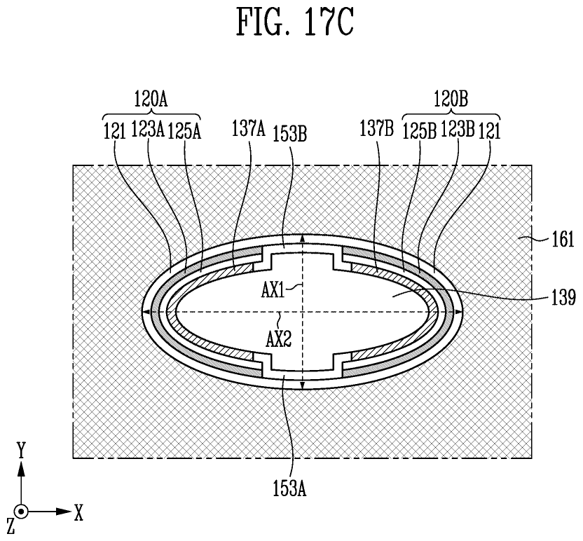

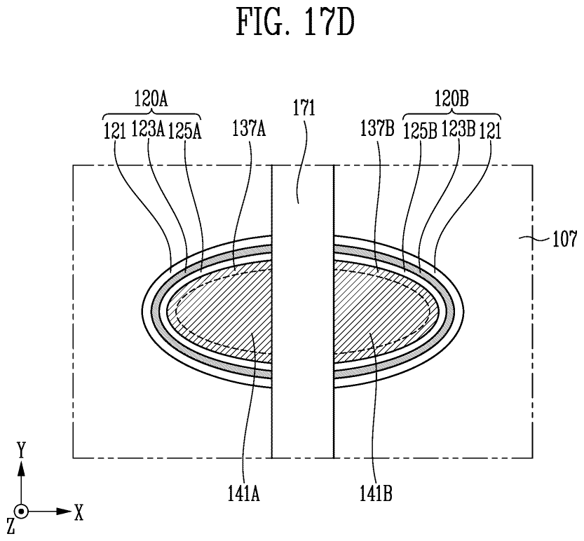

FIGS. 17A, 17B, 17C, and 17D are diagrams illustrating various configurations formed using a method of manufacturing a semiconductor memory device according to embodiments of the present disclosure. FIG. 17A illustrates cross-sections of various configurations taken along the major axis AX2 of the hole, and FIG. 17B illustrates cross-sections of various configurations taken along the minor axis AX1 of the hole. FIG. 17C is a plan view of various configurations taken along line I-I′ in FIG. 17B, and FIG. 17D is a plan view of various configurations taken along line II-II′ in FIG. 17B.

Referring to FIGS. 17A, 17B, 17C, and 17D, an isolation insulating structure 171 is formed through the capping semiconductor layer 141 shown in FIG. 16. The isolation insulating structure 171 separates the capping semiconductor layer 141 shown in FIG. 16 into a first capping portion 141A and a second capping portion 141B. The isolation insulating structure 171 extends in the direction of the minor axis AX1 of the hole to extend through the first dummy pattern 137P1B and the second dummy pattern 137P2B of the channel layer shown in FIG. 16. As a result, the first channel portion 137A and the second channel portion 137B may be separated from each other in the upper insulating layer 107 by the isolation insulating structure 171. The isolation insulating structure 171 extends farther in the direction of the minor axis AX1 compared to the minor axis AX1 of the hole and may extend through the upper insulating layer 107.

In the XY plane, each of the conductive layers 161 may extend continuously to surround the first channel portion 137A and the second channel portion 137B separated by the first channel separation structure 153A and the second channel separation structure 153B.

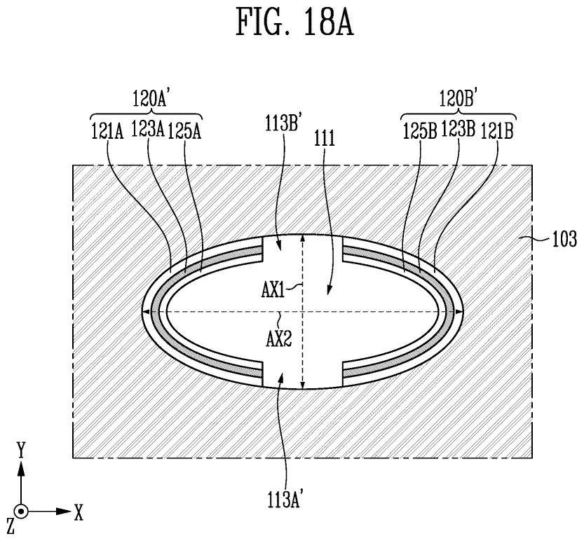

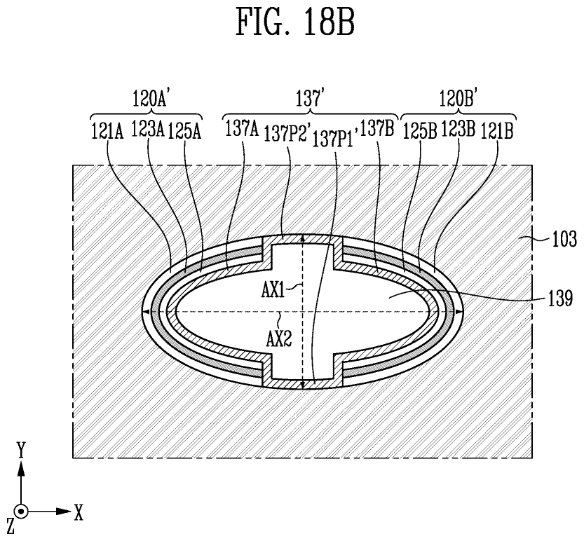

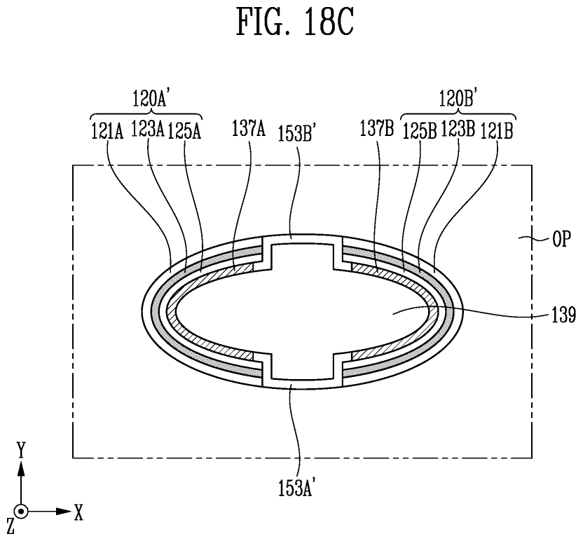

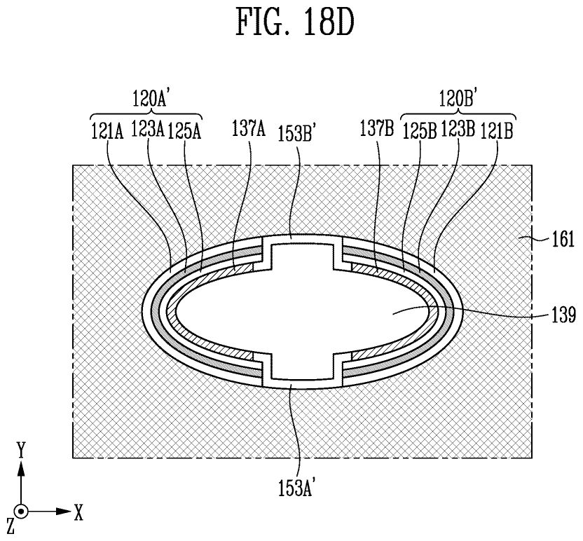

FIGS. 18A, 18B, 18C, and 18D are plan views showing various configurations formed using a method of manufacturing a semiconductor memory device according to embodiments of the present disclosure.

Prior to forming the configurations shown in FIG. 18A, the processes described above with reference to FIGS. 9A, 9B, and 9C, the processes described above with reference to FIGS. 10A and 10B, and the processes described above with reference to FIGS. 11A and 11B may be performed. As a result, the preliminary stack including the first material layer 103 as shown in FIG. 11A may be formed, and the hole 111 penetrating the preliminary stack in the Z-axis direction may be formed. The hole 111 has the minor axis AX1 and the major axis AX2 intersecting each other in the XY plane. Further, as shown in FIG. 11B, the memory layer 120 including the blocking insulating layer 121, the data storage layer 123, and the tunnel insulating layer 125 may be formed on a sidewall of the first material layer 103 adjacent to the hole 111. In addition, the first seed barrier pattern 131A and the second seed barrier pattern 131B spaced apart from each other in the direction of the major axis AX2 of the hole 111 may be formed on the inner wall of the memory layer 120. Further, the first growth barrier pattern 133A and the second growth barrier pattern 133B may be formed on the inner walls of the first seed barrier pattern 131A and the second seed barrier pattern 131B, respectively.

Subsequently, a portion of the exposed memory layer 120 between the first growth barrier pattern 133A and the second growth barrier pattern 133B as shown in FIG. 11B may be etched to form a first recess 113A′ and a second recess 113B′, as shown in FIG. 18A.

FIG. 18A is a plan view illustrating the first material layer 103 taken along the XY plane. FIGS. 18B, 18C, and 18D are plan views illustrating various configurations at levels corresponding to FIG. 18A.

Referring to FIG. 18A, the first recess 113A′ and the second recess 113B′ may be formed by etching some areas of the tunnel insulating layer, some areas of the data storage layer, and some areas of the blocking insulating layer overlapping with the minor axis AX1 of the hole 111. The first material layer 103 may be exposed by the first recess 113A′ and the second recess 113B′.

The tunnel insulating layer is separated into the first tunnel insulating pattern 125A and the second tunnel insulating pattern 125B by the first recess 113A′ and the second recess 113B′. The data storage layer is separated into the first data storage pattern 123A and the second data storage pattern 123B by the first recess 113A′ and the second recess 113B′. The blocking insulating layer is separated into a first blocking insulating pattern 121A and a second blocking insulating pattern 121B by the first recess 113A′ and the second recess 113B′. Thus, the memory layer 120 shown in FIG. 11B may be divided into a first memory pattern 120A′ including the first tunnel insulating pattern 125A, the first data storage pattern 123A, and the first blocking insulating pattern 121A, and a second memory pattern 120B′ including the second tunnel insulating pattern 125B, the second data storage pattern 123B, and the second blocking insulating pattern 121B. After forming the first memory pattern 120A′ and the second memory pattern 120B′, the first seed barrier pattern, the second seed barrier pattern, the first growth barrier pattern, and the second growth barrier pattern are selectively removed. As a result, the inner walls of the first memory pattern 120A′ and the second memory pattern 120B′ may be exposed through the hole 111, as shown in FIG. 18A.

Referring to FIG. 18B, a channel layer 137′ is formed in the hole. The channel layer 137′ is formed on the exposed inner wall of each of the first memory pattern 120A′, the second memory pattern 120B′, and the first material layer 103. The channel layer 137′ may include silicon (Si), germanium (Ge), or a mixture thereof.

The channel layer 137′ includes the first channel portion 137A, the second channel portion 137B, a first protrusion 137P1′, and a second protrusion 137P2′. The first channel portion 137A is part of the channel layer 137′ on the inner wall of the first tunnel insulating pattern 125A of the first memory pattern 120A′. The second channel portion 137B is part of the channel layer 137′ on the inner wall of the second tunnel insulating pattern 125B of the second memory pattern 120B′. The first protrusion portion 137P1′ is part of the channel layer 137′ between the first channel portion 137A and the second channel portion 137B, and protruding into the first recess 113A′. The second protrusion 137P2′ is part of the channel layer 137′ between the first channel portion 137A and the second channel portion 137B, and protruding into the second recess 113B′. Each of the first protrusion portion 137P1′ and the second protrusion portion 137P2′ is disposed on an inner wall of the first material layer 103. Each of the first protrusions 137P1′ and the second protrusions 137P2′ may extend over the inner walls of the lower insulating layer 101, each second material layer 105, and the upper insulating layers 107 shown in FIG. 13C. In contrast to the first protrusion 137P1 and the second protrusion 137P2 as shown in FIG. 13C, each of the first protrusions 137P1′ and second protrusions 137P2′ as shown in FIG. 18B may contact the inner wall of each of the lower insulating layer 101, the first material layer 103, the second material layer 105, and the upper insulation layer 107 of the preliminary stack 100 without interposing the blocking insulating layer 121.

After a channel layer 137′ as shown in FIG. 18B is formed, the core insulating layer 139 and a capping semiconductor layer may be formed in the central region of the hole surrounded by the channel layer 137′ by using the processes as described with reference to FIGS. 14A, 14B, and 14C. Subsequently, the slit 145 as shown in FIG. 14A may be formed.

Referring to FIG. 18C, by selectively removing the first material layer 103 shown in FIG. 18B through the slit, an opening OP may be formed. The first protrusion 137P1′ and the second protrusion 137P2′ of the channel layer 137′ as shown in FIG. 18B may be exposed through the opening OP. Subsequently, through the opening OP, the first protrusion 137P1′ and the second protrusion 137P2′ as shown in FIG. 18B are replaced by a first channel separation structure 153A′ and a second channel separation structure 153B′, respectively.

In an embodiment, the first channel separation structure 153A′ and the second channel separation structure 153B′ may be formed by oxidizing the first protrusion 137P1′ and the second protrusion 137P2′ as shown in FIG. 18B through the opening OP as described with reference to FIGS. 15A, 15B, 15C, 15D, and 15E. In another embodiment, after the first protrusion 137P1′ and the second protrusion 137P2′ as shown in FIG. 18B are etched through the opening OP, the first channel separation structure 153A′ and the second channel separation structure 153B′ may be formed by filling the regions where the first protrusion 137P1′ and the second protrusion 137P2′ are etched with an oxide layer.

Referring to FIG. 18D, the conductive layers 161 may be formed in the opening OP shown in FIG. 18C. The processes as described above with reference to FIGS. 17A, 17B, 17C, and 17D may then be performed.

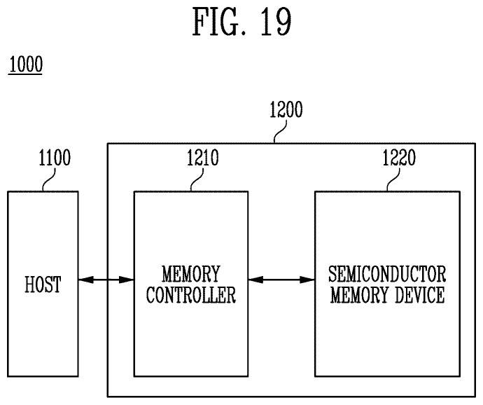

FIG. 19 is a block diagram illustrating an electronic system 1000, according to an embodiment of the present disclosure.

Referring to FIG. 19, the electronic system 1000 may be a computing system, a medical device, a communication device, a wearable device, a memory system, or the like. The electronic system 1000 may include a host 1100 and a storage device 1200.

The host 1100 may store data in the storage device 1200 or read data stored in the storage device 1200 based on an interface. The interface may include one or more of a Double Data Rate (DDR) interface, a Universal Serial Bus (USB) interface, a multimedia card (MMC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interfaces, a small computer system interface (SCSI), an enhanced small disk interface (ESDI), an Integrated Drive Electronics (IDE) interface, a Firewire interface, a Universal Flash Storage (UFS) interface, and a Nonvolatile Memory express (NVMe) interface.

The storage device 1200 may include a memory controller 1210 and a semiconductor memory device 1220. In an embodiment, the storage device 1200 may be a storage medium, such as a solid-state drive (SSD), a Universal Serial Bus (USB) memory, or the like.

The host 1100 may control the memory controller 1210 to store data in the semiconductor memory device 1220 or to read data stored in the semiconductor memory devices 1220.

The semiconductor memory device 1220 may include one memory chip or a plurality of memory chips. The semiconductor memory device 1220 may store data or output stored data in response to control of the memory controller 1210.

The semiconductor memory device 1220 may be a non-volatile memory device. The semiconductor memory device 1220 may include a hole having a cross-sectional structure with a major axis and a minor axis and extending longitudinally to include a first section through an insulating layer and a second section passing through a gate stack over the insulating layer, and a semiconductor pillar extending from the first section of the hole to the second section of the hole and including a first sidewall and a second sidewall defined based on the minor axis. The semiconductor pillar may include a first channel portion forming a first sidewall, a second channel portion forming a second sidewall and spaced apart from the first channel portion, and a connecting portion coupling the first channel portion and the second channel portion in the first section of the hole.

According to an embodiment of the present disclosure, a channel separation structure dividing a semiconductor pillar into channel portions may be formed in a hole by a process performed outside the hole without adding a process in the hole. Accordingly, the channel separation structure may be formed without adding a process in the hole, which is difficult to precisely control, thereby reducing process complexity and defects in the process of dividing the semiconductor pillar into the channel portions and improving the operation reliability of the semiconductor memory device.

What is claimed is:

1. A semiconductor memory device, comprising:
a first insulating layer including a first surface extending parallel to an XY plane;
a gate stack over the first surface of the first insulating layer and including a plurality of conductive layers and a plurality of second insulating layers, the plurality of conductive layers and the plurality of second insulating layers arranged alternately in a stacking direction crossing the XY plane;
a semiconductor pillar extending in the stacking direction and including a first section extending through the first insulating layer and a second section extending through the gate stack, the semiconductor pillar having a major axis and a minor axis in the XY plane and including a first sidewall and a second sidewall defined on opposite sides of the minor axis;
a first memory pattern between the first sidewall of the semiconductor pillar and the gate stack; and
a second memory pattern between the second sidewall of the semiconductor pillar and the gate stack,
wherein each of the first section and the second section of the semiconductor pillar comprises:
a first channel portion forming the first sidewall; and
a second channel portion forming the second sidewall and spaced apart from the first channel portion, and
wherein the first section of the semiconductor further comprises a connecting portion coupling the first channel portion and the second channel portion in the first section of the semiconductor pillar.

2. The semiconductor memory device of claim 1, further comprising a third insulating layer over the gate stack,
wherein the semiconductor pillar further comprises a first capping portion and a second capping portion extending through the third insulating layer, and
wherein the first capping portion and the second capping portion are spaced apart from each other in a direction of the major axis.

3. The semiconductor memory device of claim 2, wherein an end portion of the first channel portion extends through the third insulating layer and is integral with the first capping portion, and
wherein an end portion of the second channel portion extends through the third insulating layer and is integral with the second capping portion.

4. The semiconductor memory device of claim 3, wherein the end portion of the first channel portion and the first capping portion form a first doped semiconductor having a semi-elliptical shape in the XY plane, and
wherein the end portion of the second channel portion and the second capping portion form a second doped semiconductor pattern having a semi-elliptical shape in the XY plane.

5. The semiconductor memory device of claim 2, further comprising an isolation insulating structure between the first capping portion and the second capping portion, the isolation insulating structure extending in a direction of the minor axis.

6. The semiconductor memory device of claim 1, wherein each of the first section and the second section of the semiconductor pillar has an elliptical shape in the XY plane.

7. The semiconductor memory device of claim 1, wherein the connecting portion of the semiconductor pillar comprises a first side pattern and a second side pattern, and
wherein the first side pattern and the second side pattern are spaced apart from each other in a direction of the minor axis and extend from the first channel portion to the second channel portion.

8. The semiconductor memory device of claim 7, further comprising:
a first channel separation structure overlapping with the first side pattern in the stacking direction, and
a second channel separation structure overlapping with the second side pattern in the stacking direction,
wherein the first channel separation structure and the second channel separation structure are arranged between the first channel portion and the second channel portion in the second section of the semiconductor pillar.

9. The semiconductor memory device of claim 1, wherein the first memory pattern extends between the first channel portion of the semiconductor pillar and the first insulating layer,
wherein the second memory pattern extends between the second channel portion of the semiconductor pillar and the first insulating layer, and
wherein the connecting portion of the semiconductor pillar protrudes in a direction of the minor axis relative to the first channel portion and the second channel portion and is between the first memory pattern and the second memory pattern.

10. The semiconductor memory device of claim 1, wherein each of the first memory pattern and the second memory pattern comprises:
a tunnel insulating layer between the semiconductor pillar and the gate stack, the tunnel insulating layer extending into the first section of the semiconductor pillar;
a data storage layer between the tunnel insulating layer and the gate stack, the data storage layer extending in the first section of the semiconductor pillar; and
a blocking insulating layer between the data storage layer and the gate stack, the blocking insulating layer extending into the first section of the semiconductor pillar.

11. The semiconductor memory device of claim 10, further comprising a channel separation structure between the first channel portion and the second channel portion in the second section of the semiconductor pillar, the channel separation structure overlapping with the connecting portion of the semiconductor pillar in the stacking direction,
wherein the tunnel insulating layer is separated into a first tunnel insulating pattern and a second tunnel insulating pattern by the channel separation structure and the connecting portion of the semiconductor pillar; and
wherein the data storage layer is separated into a first data storage pattern and a second data storage pattern by the channel separation structure and the connecting portion of the semiconductor pillar.

12. The semiconductor memory device of claim 11, wherein the blocking insulating layer extends along an outer wall of each of the first data storage pattern, the second data storage pattern, the channel separation structure, and the connecting portion of the semiconductor pillar, and the blocking insulating layer has a ring shape in the XY plane.

13. The semiconductor memory device of claim 11, wherein the channel separation structure and the connecting portion of the semiconductor pillar extend in a direction of the minor axis through the blocking insulating layer, and
wherein the blocking insulating layer is separated into a first blocking insulating pattern and a second blocking insulating pattern by the channel separation structure and the connecting portion of the semiconductor pillar.

14. The semiconductor memory device of claim 1, further comprising a doped semiconductor structure over a second surface of the first insulating layer,
wherein the second surface of the first insulating layer opposes the first surface of the first insulating layer,
wherein each of the first channel portion, the second channel portion, and the connecting portion of the semiconductor pillar extends into the doped semiconductor structure, and
wherein the semiconductor pillar further comprises a horizontal portion extending parallel to the XY plane from the connecting portion.

15. The semiconductor memory device of claim 14, wherein the doped semiconductor structure comprises a contact surface in contact with each of the first channel portion, the second channel portion, the connecting portion, and the horizontal portion.

16. The semiconductor memory device of claim 14, further comprising a dummy memory pattern between the horizontal portion of the semiconductor pillar and the doped semiconductor structure, and
wherein the doped semiconductor structure comprises a contact surface in contact with each of the first channel portion, the second channel portion, and the connecting portion.
